(19) United States
(12) Patent Application Publication
(10) Pub. No.: US 2025/0128273 A1
(43) Pub. Date: Apr. 24, 2025

(54) FLUID PURIFICATION APPARATUS AND POWER DEVICE COMPRISING SAME

(71) Applicant: LS ELECTRIC CO., LTD., Anyang-si, Gyeonggi-do (KR)

(72) Inventors: Min Soo SON, Anyang-si, Gyeonggi-do (KR); Seung Pil YANG, Anyang-si, Gyeonggi-do (KR)

(21) Appl. No.: 18/682,371

(22) PCT Filed: Sep. 28, 2022
(86) PCT No.: PCT/KR2022/014535

§ 371 Date: Feb. 8, 2024

(30) Foreign Application Priority Data
Dec. 31, 2021 (KR) 10-2021-0194414

(51) Int. Cl. B04C 3/04; B04C 9/00; H05K 7/20

(52) U.S. Cl. CPC B04C 3/04; B04C 9/00; H05K 7/20272; H05K 7/20927; B04C 2009/005

(57) ABSTRACT

Disclosed are a fluid purification apparatus and a power device comprising the same. The fluid purification apparatus comprises a frame portion having a space formed therein; a cover portion covering the space and coupled to the frame portion; and purification modules each of which passes through the frame and cover portion, and communicates with the outside and the space, wherein each purification module comprises a body portion forming a part of the exterior and having an inner portion that communicates with the outside and the space to form a flow path through which a fluid from the outside flows; and a vortex formation member accommodated in the body portion and provided to turn the fluid flow from the outside into the body portion into a vortex. Thus, dust mixed in the fluid from the outside can be centrifuged from the fluid while flowing in the vortex in the body portion.

### CROSS-REFERENCE TO RELATED APPLICATIONS

This application is a National Stage of International Application No. PCT/KR2022/014535, filed on Sep. 28, 2022, which claims priority to and the benefit of Korean Patent Application No. 10-2021-0194414, filed on Dec. 31, 2021, the disclosures of which is incorporated herein by reference in its entirety.

### FIELD

The present disclosure relates to a fluid purification apparatus and a power device including the same, and more specifically to a fluid purification apparatus which is capable of pre-removing dust mixed in a fluid for cooling and a power device including the same.

### BACKGROUND

Power devices refer to devices which are capable of converting and transmitting power by conducting electricity with external power sources and loads. The power devices may receive power from an external power source, boost or step down the power, and transmit the power to an external load.

In order to perform the above functions, various electrical devices are mounted inside the power device. As mounted electrical devices operate, heat is generated inside the power device. When the generated heat stays inside the power device, there is a possibility that the electrical devices may be thermally damaged.

Therefore, a typical power device includes a component for cooling mounted electrical devices. For example, the power device may cool mounted electrical devices in the form of air cooling by using external air.

However, various foreign substances such as dust and dirt may be mixed in the external air. When external air is introduced into the power device without a separate filtering process, mounted electrical devices may be damaged by foreign substances mixed in the external air for air cooling.

In order to prevent this, a filter is provided at a part where the power device communicates with the outside. The filter is configured to filter incoming external air and filter out foreign substances mixed with the external air.

As the usage of power devices progresses, a significant amount of foreign substances accumulates in the filter. In this case, it is difficult to smoothly introduce the outside air, and the reliability of the filtration process may also be deteriorated. Furthermore, since the replacement cycle of the filter is shortened, time and cost required for operation of the power device may increase.

Korean Registered Patent No. 10-1476003 discloses a cabinet with modules having a thermosiphon cooler arrangement. Specifically, a cabinet having modules having a thermosiphon cooler arrangement which is capable of guiding a flow of incoming cooling air with a separate first aperture to receive the stream of cooling air is disclosed.

However, the cabinet disclosed in the related art document only provides a method for guiding the flow of air for cooling, but does not suggest a method for filtering foreign substances mixed in the air.

Korean Registered Patent No. 10-0896777 discloses a multiple power supply device having improved mountability. Specifically, a multiple power supply device which is capable of introducing cooling air for cooling the power device by including a separate cooling fan is disclosed.

However, the multiple power supply device presented in the related art document also only proposes a method for introducing air for cooling into the inside, but does not suggest a method for filtering foreign substances mixed in the air for cooling.

Korean Registered Patent No. 10-1476003 (Dec. 23, 2014)

Korea Registered Patent No. 10-0896777 (May 11, 2009)

### SUMMARY

The present disclosure has been devised to solve the above problems, and an object of the present disclosure is to provide a fluid purification apparatus having a structure which is capable of effectively removing foreign substances mixed with a fluid introduced for cooling, and a power device including the same.

Another object of the present disclosure is to provide a fluid purification apparatus having a structure in which foreign substances mixed with a fluid introduced for cooling can be removed several times, and a power device including the same.

Still another object of the present disclosure is to provide a fluid purification apparatus having a structure in which foreign substances mixed in a fluid introduced for cooling can be removed in various forms according to the size thereof, and a power device including the same.

Still another object of the present disclosure is to provide a fluid purification apparatus having a structure in which the number of members for removing foreign substances can be adjusted according to the capacity thereof, and a power device including the same.

Still another object of the present disclosure is to provide a fluid purification apparatus having a structure in which the durability of a filter for filtering foreign substances mixed in a fluid can be increased, and a power device including the same.

The problems of the present disclosure are not limited to the problems mentioned above, and other problems that are not mentioned will be clearly understood by those skilled in the art from the description below.

According to an aspect of the present disclosure, provided is a fluid purification apparatus, including a frame portion having a space formed therein; a cover portion covering the space of the frame portion and coupled to the frame portion; and purification modules each of which passes through the frame portion and the cover portion, and is in communication with the outside and the space in the frame portion, wherein each purification module includes a body portion forming a part of the exterior and having an inner portion that is in communication with the outside and the space in the frame portion to form a flow path through which a fluid from the outside flows; and a vortex formation member accommodated in the body portion and provided to turn the fluid flow from the outside into the body portion into a vortex such that dust mixed in the fluid from the outside is centrifuged from the fluid while flowing in the vortex in the body portion.

In this case, the fluid purification apparatus may be provided, wherein the cover portion includes a first cover which is located on the outermost side and to which a part of the purification module is coupled; and a second cover which is disposed to be spaced apart from the first cover along a direction in which the body portion of the purification module extends, and to which another part of the purification module is coupled.

In addition, the fluid purification apparatus may be provided, wherein the first cover includes a first plate which forms an exterior thereof; and a first coupling opening which is formed to penetrate through the inside of the first plate in the thickness direction, and through which the purification module is coupled to penetrate.

In this case, the fluid purification apparatus may be provided, wherein the second cover includes a second plate which forms an exterior thereof; and a second coupling opening which is formed to penetrate through the inside of the second plate in the thickness direction, and through which the purification module is coupled to penetrate.

In addition, the fluid purification apparatus may be provided, wherein the frame portion includes a first frame which is located between the first cover and the second cover, the inside of which is sealed by the first cover and the second cover: a second frame which is disposed to face the first frame with the second cover therebetween, and has a space formed therein through which the fluid passing through the purification module flows; and a coupling frame which is disposed to face the second cover with the second frame therebetween, and has a space formed therein for accommodating a filter member through which the fluid passes.

In this case, the fluid purification apparatus may be provided, wherein the first frame includes a first frame outer periphery which forms an exterior; and a first frame space which is formed to be surrounded by the first frame outer periphery, is sealed by the first cover and the second cover, and is in communication with the inside of the body portion of the purification module, into which the centrifuged dust flows.

In addition, the fluid purification apparatus may be provided, wherein the second frame includes a second frame outer periphery which forms an exterior; and a second frame space which is formed to be surrounded by the second frame outer periphery, and is sealed by the second cover, the coupling frame and a filter member that is accommodated in the coupling frame, and through which the fluid from which the dust has been separated flows.

In this case, the fluid purification apparatus may be provided, wherein a body hollow which is formed to penetrate in the extension direction of the body portion is formed inside the body portion, and wherein one end of the body hollow in the extension direction is formed to be open such that the external fluid flows in, and the other end thereof in the extension direction is formed to be open such that the fluid from which the dust has been removed flows out.

In addition, the fluid purification apparatus may be provided, wherein the frame portion includes a first frame having a first frame space formed therein into which the centrifuged dust flows; and a second frame having a second frame space formed therein into which the fluid from which the dust has been separated flows.

In this case, the fluid purification apparatus may be provided, wherein the body portion includes a dust discharge portion which is formed to penetrate through the outer periphery and communicates with the inside of the body portion and the first frame space, and wherein the dust separated from the inside of the body portion passes through the dust discharge portion and is discharged into the first frame space.

In addition, the fluid purification apparatus may be provided, wherein the body portion is formed to extend in one direction such that one end in the extension direction of the body portion is exposed to the outside, and the other end in the extension direction of the body portion is accommodated inside the frame portion, and wherein the vortex forming member is provided in plurality, and the plurality of vortex forming members are spaced apart from each other along the one direction and are disposed inside the body portion.

In this case, the fluid purification apparatus may be provided, wherein the vortex forming member includes a first vortex forming member which is located adjacent to the one end in the extension direction of the body portion and forms the flow of the fluid flowing into the body portion into a vortex shape.

In addition, the fluid purification apparatus may be provided, wherein the first vortex forming member includes a vortex axis which is located at the central axis of the body portion; and a plurality of blades which extend in a curved shape between the vortex axis and the inner periphery of the body portion.

In this case, the fluid purification apparatus may be provided, wherein the vortex forming member includes a second vortex forming member which is located adjacent to the other end in the extension direction of the body portion and forms the flow of the fluid flowing into the body portion into a vortex shape.

In addition, the fluid purification apparatus may be provided, wherein the second vortex forming member is formed to have a reduced cross-sectional area along a direction toward the one end in the extension direction of the body portion, and wherein the interior of the second vortex forming member includes a vortex hollow which is formed to penetrate through and communicates with the interior of the body portion and the interior of the frame portion, and through which the fluid from which the dust has been removed flows.

In addition, according to an aspect of the present disclosure, provided is a power device, including a housing which has a space formed inside that communicates with the outside: a filter member which is coupled to one surface of the housing to filter an external fluid flowing into the space of the housing; and a fluid purification apparatus which covers the filter member and is coupled to the housing, and centrifugally separates dust mixed in the external fluid flowing into the space of the housing, wherein the fluid purification apparatus and the filter member are arranged to overlap along a direction in which the external fluid flows into the space of the housing such that the external fluid sequentially passes through the fluid purification apparatus and the filter member to flow into the space of the housing.

In this case, the power device may be provided, wherein the fluid purification apparatus includes a frame portion which is physically partitioned and has a plurality of spaces formed therein through which the dust and the fluid from which the dust has been removed flow respectively: a cover portion which seals each of the plurality of spaces of the frame portion and is coupled to the frame portion; and a purification module which is configured to communicate with the outside, allow the fluid to flow in, and centrifugally separate the dust by forming the flow of the introduced fluid into a vortex shape, and respectively communicates with the plurality of spaces of the frame portion and discharges the separated dust and the fluid from which the dust has been separated into the plurality of spaces.

In addition, the power device may be provided, wherein the purification module includes a first vortex forming member which is located at one end of the extension direction and forms the flow of the introduced fluid into a vortex shape; and a second vortex forming member which is located at the other end of the extension direction and forms the flow of the introduced fluid into a vortex shape.

According to the configuration described above, the fluid purification apparatus according to an exemplary embodiment of the present disclosure and a power device including the same can effectively remove foreign substances mixed with the fluid introduced for cooling.

First of all, the fluid purification apparatus includes a purification module. The purification module includes a plurality of vortex forming members to form the flow of a fluid introduced from the outside in a vortex shape. As the fluid flows inside the purification module, the dust mixed with the fluid is moved radially outward by centrifugal force and is centrifuged.

A dust discharge portion is formed through the outer periphery of the purification module. The centrifuged dust is discharged into any one of the spaces of the frame portion through the dust discharge portion. The fluid from which dust and the like have been separated may flow into the power device through a filter member.

Accordingly, dust mixed in the fluid may be separated not only by the filtering process but also by centrifugal separation. Accordingly, foreign substances mixed with the fluid flowing into the power device for cooling may be effectively removed.

In addition, according to the configuration described above, in the fluid purification apparatus according to an exemplary embodiment of the present disclosure and the power device including the same, foreign substances mixed with the fluid introduced for cooling may be removed several times.

The external fluid may be introduced into the power device only when it sequentially passes through the fluid purification apparatus and the filter member. That is, the introduced external fluid is primarily filtered by the fluid purification apparatus and then is secondarily filtered by the filter member.

Accordingly, the external fluid may primarily remove dust through a centrifugal separation process by the fluid purification apparatus and secondarily remove dust by the filter member and then flow into the power device. Accordingly, dust and the like mixed with the fluid can be removed multiple times, and the degree of purification of the introduced fluid can be improved.

In addition, according to the configuration described above, in the fluid purification apparatus according to an exemplary embodiment of the present disclosure and the power device including the same, foreign substances mixed in the fluid introduced for cooling may be removed in various forms according to the sizes thereof.

The external fluid undergoes a centrifugal separation process by the fluid purification apparatus. The magnitude of the centrifugal force is proportional to the magnitude of the mass of the material to which the centrifugal force is applied. Therefore, by the centrifugal separation process, dust having larger particles and mass among foreign substances mixed with the external fluid may be separated.

The filter member is configured to filter minute-sized particles and dust having a mass remaining in the external fluid. That is, the fluid in a state in which relatively large particles and dust having a mass are previously removed passes through the filter member.

Therefore, the foreign substances mixed with the external fluid are introduced into the power device after being removed in various forms according to the size and mass thereof. Accordingly, the foreign substances may be removed in various ways due to the physical properties of the foreign substances to be removed.

In addition, according to the configuration described above, the number of members for removing foreign substances may be adjusted according to the capacity of the fluid purification apparatus according to an exemplary embodiment of the present disclosure and the power device including the same.

The purification module provided in the fluid purification apparatus may be detachably coupled to the cover portion. The number of purification modules may be adjusted according to the capacity of the power device, that is, the amount of heat generated by the devices provided inside the power device.

In an exemplary embodiment, the number of purification modules and the number of coupling openings through which the purification modules are formed in the cover portion may be changed according to the capacity of the power device. Alternatively, a sufficient number of coupling openings may be formed in the cover portion, and the purification module may be coupled to only some of a plurality of coupling openings.

Accordingly, the number of purification modules provided may be adjusted according to the capacity of the power device. Accordingly, the degree of freedom in design is improved, and it is possible to actively respond according to the capacity of the power device.

In addition, according to the configuration described above, in the fluid purification apparatus according to an exemplary embodiment of the present disclosure and the power device including the same, the durability of the filter for filtering foreign substances mixed with the fluid may be increased.

According to the configuration described above, among the foreign substances mixed with the external fluid, relatively large-sized dust and the like are separated by the fluid purification apparatus. That is, dust mixed with the fluid flowing into the filter member has a minute size.

Accordingly, clogging of the filter member due to dust or the like separated by the filter member can be minimized. Accordingly, damage to the filter member can be prevented, and durability can be increased.

The effects of the present disclosure are not limited to the above effects, and should be understood to include all effects that can be inferred from the detailed description of the present disclosure or the configuration of the disclosure described in the claims.

### BRIEF DESCRIPTION OF THE DRAWINGS

FIG. 1 is a perspective view illustrating a power device according to an exemplary embodiment of the present disclosure.

FIG. 2 is a perspective view from another angle illustrating the power device of FIG. 1.

FIG. 3 is a perspective view illustrating a fluid purification apparatus included in the power device of FIG. 1.

FIG. 4 is a side view illustrating the fluid purification apparatus of FIG. 3.

FIG. 5 is a perspective view from another angle illustrating the fluid purification apparatus of FIG. 3.

FIG. 6 is an exploded perspective view illustrating the fluid purification apparatus of FIG. 3.

FIG. 7 is an exploded perspective view illustrating parts of a cover portion and a purification module provided in the fluid purification apparatus of FIG. 3.

FIG. 8 is a perspective view illustrating a part of a purification module included in the fluid purification apparatus of FIG. 3.

FIG. 9 is a partially cut-away perspective view illustrating a part of the purification module of FIG. 8.

FIG. 10 is an exploded perspective view illustrating another part of a cover portion and a purification module provided in the fluid purification apparatus of FIG. 3.

FIG. 11 is a perspective view illustrating another part of the purification module of FIG. 10.

FIG. 12 is a partially cut-away perspective view illustrating another part of the purification module of FIG. 10.

FIG. 13 is a partially cut-away perspective view illustrating the flow process of a fluid formed in the fluid purification apparatus of FIG. 3.

FIG. 14 is a side cross-sectional view illustrating the flow process of a fluid formed in the power device of FIG. 1.

FIG. 15 is a partially enlarged side cross-sectional view illustrating the flow process of a fluid formed in the fluid purification apparatus of FIG. 3.

### DETAILED DESCRIPTION

Hereinafter, with reference to the accompanying drawings, the exemplary embodiments of the present disclosure will be described in detail so that those skilled in the art can easily practice the present disclosure. The present disclosure may be embodied in many different forms and is not limited to the exemplary embodiments described herein. In order to clearly describe the present disclosure, parts that are irrelevant to the description are omitted in the drawings, and the same reference numerals are assigned to the same or similar components throughout the specification.

Words and terms used in the present specification and claims are not construed as limited in their ordinary or dictionary meanings, but in accordance with the principle that the inventors can define terms and concepts in order to best describe their disclosures, they must be interpreted as meanings and concepts that correspond to the technical ideas of the present disclosure.

Therefore, the exemplary embodiments described in the present specification and the configurations illustrated in the drawings correspond to a preferred exemplary embodiment of the present disclosure, and do not represent all the technical ideas of the present disclosure, and thus, there may be equivalents and variations for the corresponding configurations that may replace the same at the time of filing of the present disclosure.

In the following description, the descriptions of some components may be omitted to clarify the characteristics of the present disclosure.

### 1. Definition of Terms

The term “electrical conduction” used in the following description means that one or more members are connected to transmit current or electrical signals. In an exemplary embodiment, the current may be formed in a wired form by a wire member or the like or a wireless form such as Wi-Fi, Bluetooth or RFID.

The term “communication” used in the following description means that one or more members are fluidly connected to each other. In an exemplary embodiment, the communication may be formed by opening the insides of each member to each other or by other members such as conduits and pipes.

The term “fluid” used in the following description refers to any form of material that can flow by external pressure or force. In an exemplary embodiment, the fluid may be provided with air, particularly air remaining outside a power device 1.

The term “dust” used in the following description means a foreign substance mixed with a fluid. In an exemplary embodiment, dust may be used to collectively refer to small-sized particles that may cause damage to components when it is introduced into the power device 1.

The terms “upper side”, “lower side”, “left side”, “right side”, “front side” and “back side” used in the following description will be understood with reference to the coordinate system illustrated throughout the accompanying drawings.

### 2. Description of the Configuration of the Power Device 1 According to an Exemplary Embodiment of the Present Disclosure

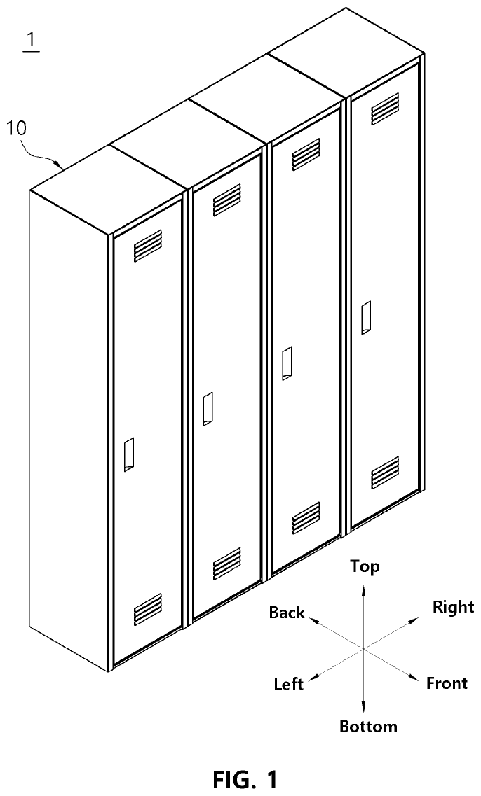

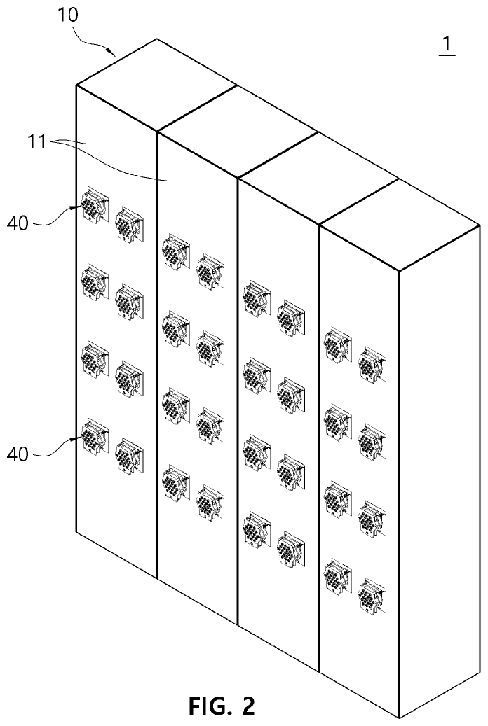

Referring to FIGS. 1 and 2, the power device 1 according to an exemplary embodiment of the present disclosure is illustrated. The power device 1 may be provided in any shape which is capable of performing a predetermined function by conducting electricity with an external power source or load. In an exemplary embodiment, the power device 1 may be equipped with an energy storage system (ESS).

Various components may be mounted inside the power device 1. The components may be configured to perform various functions by conducting electricity with an external power source or load.

The power device 1 may be provided in any shape which is capable of performing a predetermined function. In the illustrated exemplary embodiment, the power device 1 is formed such that a plurality of rectangular pillar-shaped frames are continuously disposed with each other in the width direction. Modules that independently conduct electricity with external power and loads may be accommodated inside each frame.

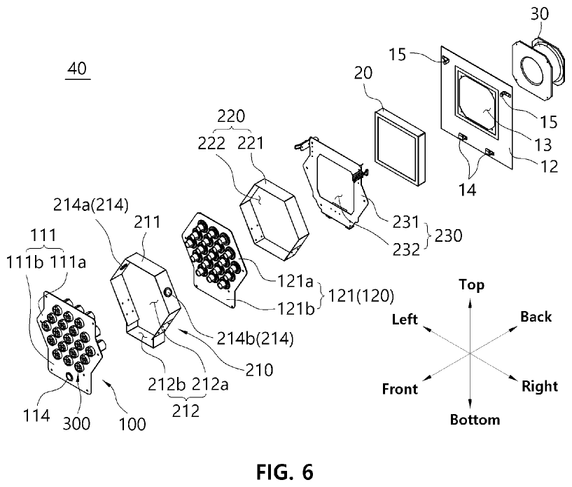

In the illustrated exemplary embodiment, the power device 1 includes a housing 10 and a fluid purification apparatus 40. In addition, further referring to FIG. 6, the power device 1 further includes a filter member 20 and a blowing fan 30.

Hereinafter, the components of the power device 1 will be described with reference to the accompanying drawings, but the fluid purification apparatus 40 will be described separately.

The housing 10 forms an exterior of the power device 1. A space is formed inside the housing 10, and various components for operating the power device 1 may be mounted.

The space formed inside the housing 10 is closed and is configured not to be exposed to the outside. Although reference numerals are not assigned, the front side of the housing 10 may be opened and closed by a door. In addition, the back side of the housing 10 is surrounded by the outer surface 11 and may not be exposed to the outside. Furthermore, other parts of the housing 10 may also be closed by the surfaces constituting the housing 10.

In the illustrated exemplary embodiment, the housing 10 includes an outer surface 11, a filter frame 12, a filter opening 13, a support protrusion 14 and a coupling protrusion 15.

The outer surface 11 is defined as one surface surrounding the inner space of the housing 10. In the illustrated exemplary embodiment, the exterior surface 11 is the back side surface of the housing 10. The outer surface 11 is disposed to surround the inner space of the housing 10 from the back side.

Although not illustrated, a through-hole may be formed on the outer surface 11. The through-hole may be configured to communicate the inner space of the housing 10 with the outside. A plurality of through-holes may be formed at various locations on the outer surface 11.

A fluid purification apparatus 40 is coupled to the outer surface 11. The fluid purification apparatus 40 is coupled to the housing 10 while covering the through-hole. Therefore, the external fluid must pass through the fluid purification apparatus 40 to be introduced into the housing 10.

A filter frame 12 is coupled to the outer surface 11.

The filter frame 12 supports the filter member 20. The filter frame 12 is coupled to the outer surface 11 while covering the through-hole formed on the outer surface 11. That is, the external fluid must pass through the filter member 20 to be introduced into the housing 10.

The filter frame 12 may be of any shape which is capable of supporting the filter member 20. In the exemplary embodiment illustrated in FIG. 6, the filter frame 12 has a rectangular plate shape with filter openings 13 which are formed to penetrate therethrough.

A plurality of filter frames 12 may be provided. A plurality of filter frames 12 may be coupled to the outer surface 11 while covering a plurality of through-holes formed on the outer surface 11.

The filter frame 12 is coupled to the fluid purification apparatus 40. In the illustrated exemplary embodiment, the filter frame 12 is positioned between the outer surface 11 and the fluid purification apparatus 40.

The filter opening 13 is a space through which the filter member 20 penetrates. The filter opening 13 is formed to penetrate through the inside of the filter frame 12. The filter opening 13 may be defined as a space surrounded by an inner periphery of the filter frame 12.

The filter opening 13 may have any shape through which the filter member 20 may penetrate and be supported by the filter frame 12. In the illustrated exemplary embodiment, the filter opening 13 has a rectangular cross-section and is formed through the filter frame 12 in the thickness direction, that is, in the front-back direction.

The support protrusion 14 is a part where the filter frame 12 is coupled to the fluid purification apparatus 40. The support protrusion 14 extends from one side of the filter frame 12 towards the fluid purification apparatus 40 by a predetermined length. In the exemplary embodiment illustrated in FIG. 6, the support protrusion 14 is disposed on the lower side of the filter frame 12 and extends forward toward the fluid purification apparatus 40 by a predetermined length.

The support protrusion 14 is coupled to a hinge member (reference numeral not assigned) provided in the fluid purification apparatus 40. Specifically, the support protrusion 14 may be rotatably coupled to a hinge member (reference numeral not assigned) by an axis member (reference numeral not assigned).

A plurality of support protrusions 14 may be provided. The plurality of support protrusions 14 may be spaced apart from each other and coupled to the fluid purification apparatus 40 at different positions. In the illustrated exemplary embodiment, two support protrusions 14 are provided and disposed to be spaced apart from each other in the left-right direction.

The coupling protrusion 15 is another part where the filter frame 12 is coupled to the fluid purification apparatus 40. The coupling protrusion 15 extends from one side of the filter frame 12 toward the fluid purification apparatus 40 by a predetermined length. In the exemplary embodiment illustrated in FIG. 6, the coupling protrusion 15 is disposed on the upper side of the filter frame 12 and extends forward toward the fluid purification apparatus 40 by a predetermined length.

The coupling protrusion 15 is coupled to a coupling member (reference numeral not assigned) provided in the fluid purification apparatus 40. Specifically, the coupling protrusion 15 may be detachably coupled to a coupling member (reference numeral not assigned).

Therefore, the fluid purification apparatus 40 may be disengaged from the coupling protrusion 15 in a state of being coupled to the support protrusion 14, and rotated around the support protrusion 14.

A plurality of coupling protrusions 15 may be provided. The plurality of coupling protrusions 15 may be spaced apart from each other and detachably coupled to the fluid purification apparatus 40 at different positions. In the illustrated exemplary embodiment, two coupling protrusions 15 are disposed to be spaced apart from each other in the left-right direction. In this case, the pair of coupling protrusions 15 may be disposed to face each other with the filter opening 13 interposed therebetween.

The filter member 20 filters a fluid introduced into the inner space of the housing 10 from the outside of the power device 1. The fluid introduced from the outside must pass through the filter member 20 to be introduced into the inner space of the housing 10.

Specifically, the filter member 20 is inserted into the filter opening 13 formed inside the filter frame 12 and coupled to the outer surface 11 together with the filter frame 12. In this case, the filter member 20 covers the through-hole formed on the outer surface 11 and is coupled. The external fluid may flow into the inner space of the housing 10 through the through-hole only after passing through the filter member 20 and being filtered.

The filter member 20 may be provided in any shape which is capable of filtering the passing fluid and removing foreign substances and the like. In an exemplary embodiment, the filter member 20 may include a pre-filter for filtering relatively large particle foreign substances and a HEPA filter for filtering relatively small particle foreign substances.

The filter member 20 is coupled to the coupling frame 230. Specifically, the filter member 20 is supported by the outer periphery 231 of the coupling frame 230 through the filter accommodating portion 232 which is formed to penetrate the inside of the coupling frame 230.

The filter member 20 filters a fluid flowing into the housing 10 and may have any shape that can be supported by the filter frame 12 and the coupling frame 230. In the illustrated exemplary embodiment, the filter member 20 is formed in a rectangular plate shape having a rectangular cross-section and having a thickness in the front-back direction.

A plurality of filter members 20 may be provided. A plurality of filter members 20 may be disposed to cover the plurality of through-holes formed on the outer surface 11, respectively.

A blowing fan 30 provides a transfer force for introducing an external fluid into the housing 10. The fluid introduced by the blower fan 30 exchanges heat with various components of the power device 1 such that the components may be cooled.

The blowing fan 30 is accommodated in the inner space of the housing 10. The blowing fan 30 may be coupled to one surface of the housing 10, which is the inner side of the outer surface 11 in the illustrated exemplary embodiment. In this case, the blowing fan 30 may be coupled to the outer surface 11 while covering the through-hole formed on the outer surface 11.

That is, the blowing fan 30 is disposed to face the filter member 20 and the fluid purification apparatus 40 with the outer surface 11 interposed therebetween. The transfer force generated by the blowing fan 30 may pass through the filter member 20 and the fluid purification apparatus 40 and be transferred to an external fluid.

When the blowing fan 30 is operated, the fluid remaining outside the housing 10 may pass through the fluid purification apparatus 40 and the filter member 20 sequentially and be introduced into the housing 10. Therefore, the fluid may be introduced into the housing 10 after at least two purification processes. As a result, foreign substances mixed in the fluid may be effectively removed.

The blowing fan 30 may be provided in any shape which is capable of providing a transfer force to the fluid. In an exemplary embodiment, the blower fan 30 may include a plurality of blades and may be provided in a shape which is capable of sucking a fluid by being rotated. In the above exemplary embodiment, the blowing fan 30 may conduct electricity with an external power source (not illustrated).

The blowing fan 30 is disposed to overlap the filter member 20 and the fluid purification apparatus 40 in a direction in which the external fluid is introduced, that is, in a direction from the back side to the front side in the illustrated exemplary embodiment.

A plurality of blowing fans 30 may be provided. A plurality of blowing fans 30 may be coupled to the inside of the outer surface 11 at different positions. In this case, the plurality of blowing fans 30 may be coupled while covering the plurality of through-holes, respectively.

### 3. Description of the Configuration of the Fluid Purification Apparatus 40 According to an Exemplary Embodiment of the Present Disclosure

Referring back to FIG. 2, the power device 1 according to the illustrated exemplary embodiment includes a fluid purification apparatus 40.

The fluid purification apparatus 40 primarily filters an external fluid flowing into the housing 10. The fluid that passes through the fluid purification apparatus 40 and is primarily filtered may pass through the filter member 20 and be filtered secondarily.

The fluid purification apparatus 40 may be configured to filter dust having a relatively large size compared to the filter member 20. That is, the fluid passing through the filter member 20 may be in a state in which relatively large dust is removed.

Accordingly, clogging of the filter member 20 due to relatively large amounts of dust contained in the external fluid may be prevented. Accordingly, the filtration efficiency of the filter member 20 is improved, and the duration thereof may be extended.

The fluid purification apparatus 40 may be provided in any shape which is capable of removing relatively large-sized dust mixed with an external fluid. In the illustrated exemplary embodiment, the fluid purification apparatus 40 may be configured to separate dust that is mixed with an external fluid in the centrifugation separation method.

The fluid purification apparatus 40 is coupled to the housing 10. Specifically, the fluid purification apparatus 40 is coupled to one surface of the housing 10, which is the outer surface 11 in the illustrated exemplary embodiment.

The fluid purification apparatus 40 covers and is coupled to the through-hole formed on the outer surface 11. Accordingly, the fluid purification apparatus 40 is disposed to face the blowing fan 30 with the outer surface 11 or the filter frame 12 interposed therebetween. That is, the fluid purification apparatus 40 may communicate with the inner space of the housing 10 through the through-hole.

The fluid purification apparatus 40 covers the filter member 20 and is coupled to the outer surface 11. The external fluid may flow to the filter member 20 only when it passes through the fluid purification apparatus 40. Accordingly, the external fluid may be introduced into the inner space of the housing 10 after undergoing a plurality of filtering processes.

The fluid purification apparatus 40 communicates with the through-hole formed on the outer surface 11, the filter member 20 and the blowing fan 30. The external fluid that has passed through the fluid purification apparatus 40 may be introduced into the inner space of the housing 10 through the filter member 20, the through-hole and the blowing fan 30 sequentially.

The fluid purification apparatus 40 may be detachably coupled to the outer surface 11. As described above, the fluid purification apparatus 40 may be coupled to the support protrusion 14 and the coupling protrusion 15, respectively. In this case, the fluid purification apparatus 40 may be rotatably coupled to the support protrusion 14 and detachably coupled to the coupling protrusion 15.

Therefore, in an exemplary embodiment, the fluid purification apparatus 40 may be rotatably coupled to the housing 10 about the support protrusion 14.

A plurality of fluid purification apparatuses 40 may be provided. A plurality of fluid purification apparatuses 40 may be disposed on the outer surface 11 to be spaced apart from each other so as to cover the plurality of through-holes. It will be understood that by the above arrangement, the plurality of fluid purification apparatuses 40 are coupled to the outer surface 11 while also covering the plurality of filter members 20 and the plurality of blowing fans 30.

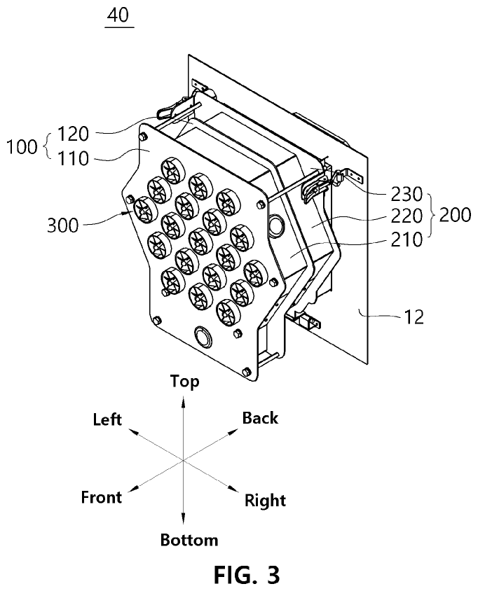

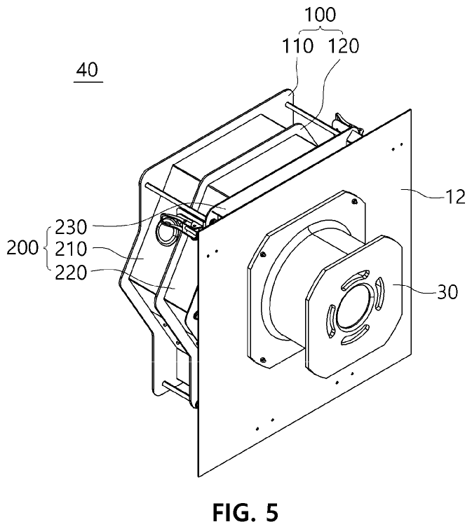

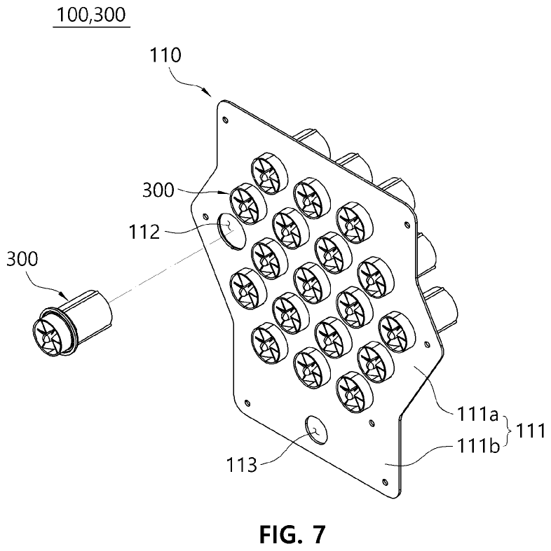

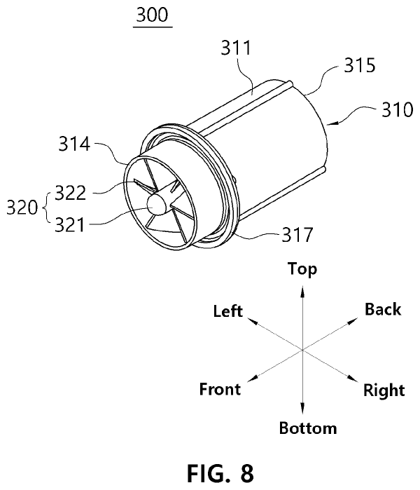

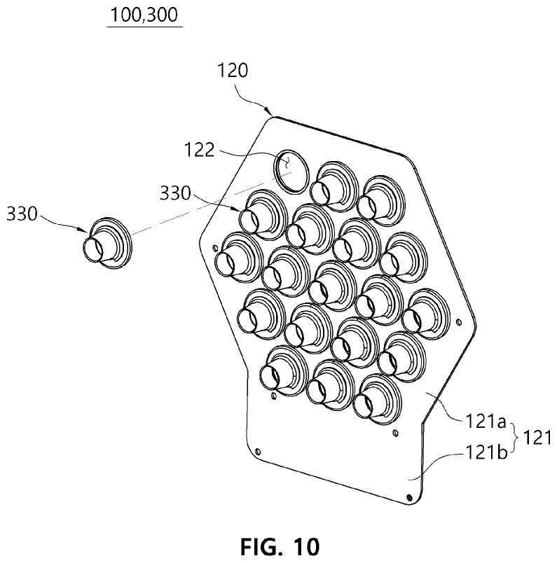

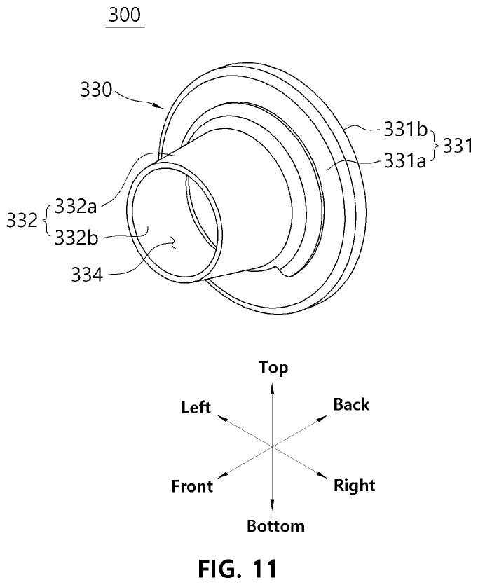

Hereinafter, the fluid purification apparatus 40 according to an exemplary embodiment of the present disclosure will be described in detail with reference to FIGS. 3 to 12. In the illustrated exemplary embodiment, the fluid purification apparatus 40 includes a cover portion 100, a frame portion 200 and a purification module 300.

The cover portion 100 forms a part of the exterior of the fluid purification apparatus 40. A through-hole is formed in the cover portion 100 such that the purification module 300 may be coupled to penetrate. That is, the cover portion 100 is configured to support the purification module 300.

The cover portion 100 is coupled to the frame portion 200. The cover portion 100 forms a space therebetween and is coupled to the frame portion 200. The purification module 300 may be partially accommodated in the space. In addition, the fluid that has passed through the purification module 300 may flow in the space.

The cover portion 100 may be closely coupled to the frame portion 200. That is, a space formed between the cover portion 100 and the frame portion 200 is sealed by the cover portion 100 and the frame portion 200 such that any communication with the outside may be blocked. Therefore, the external fluid must pass through the purification module 300 to be introduced into the space formed between the cover portion 100 and the frame portion 200.

The cover portion 100 is arranged to overlap the filter member 20, the blowing fan 30 and the frame portion 200 in the thickness direction thereof, which is the front-back direction in the illustrated exemplary embodiment.

A plurality of cover portions 100 may be provided. The plurality of cover portions 100 may be respectively positioned between the plurality of frame portions 200. In the illustrated exemplary embodiment, the cover portion 100 includes a first cover 110 which is coupled to the first frame 210 and a second cover 120 which is coupled to the first frame 210 and the second frame 220, respectively.

The first cover 110 forms the outermost part of the fluid purification apparatus 40. In the illustrated exemplary embodiment, the first cover 110 forms the front side end of the fluid purification apparatus 40. In other words, the first cover 110 is disposed to be most spaced apart from the housing 10 among the components of the fluid purification apparatus 40.

The first cover 110 is coupled to the first frame 210. Specifically, the first cover 110 covers the first frame space 212 formed inside the first frame 210 from the outside, that is, from the front side in the illustrated exemplary embodiment, and is coupled to the first frame 210. In an exemplary embodiment, it is as described above that the first cover 110 and the first frame 210 may be closely coupled.

The first cover 110 is coupled to the coupling frame 230. That is, in the exemplary embodiment illustrated in FIG. 3, the first cover 110 may be coupled to the coupling frame 230 which is positioned on the back side by a plurality of fastening members (reference numeral not assigned). By the coupling, other components that are positioned between the first cover 110 and the coupling frame 230 may be tightly coupled to each other.

The first cover 110 is coupled to a purification module 300. The first cover 110 is configured to support a part of the purification module 300, which is the front side in the illustrated exemplary embodiment. This is achieved by penetrating and coupling the purification module 300 to the first coupling opening 112 formed on the first cover 110. In the illustrated exemplary embodiment, the first cover 110 supports the body portion 310 of the purification module 300.

The first cover 110 may be coupled to the first frame 210 to seal the first frame space 212 and may have any shape which is capable of partially supporting the purification module 300. In the illustrated exemplary embodiment, the first cover 110 has a polygonal plate shape including a plurality of corners.

Specifically, in the illustrated exemplary embodiment, the first cover 110 includes a first portion which is located on the upper side and extends in a horizontal direction, and a pair of second portions including one bent portion which extends downward from each end of the first portion and protrudes outward. Additionally, in the illustrated exemplary embodiment, the first cover 110 includes a third portion which extends vertically downward from each end of the second portion and a fourth portion which extends between each end of the third portion.

In the illustrated exemplary embodiment, the first cover 110 includes a first plate 111, a first coupling opening 112, a cover communication hole 113 and a cover cap 114.

The first plate 111 forms the body of the first cover 110. The first plate 111 is provided in a plate shape and coupled to the first frame 210. The first plate 111 is disposed to cover the first frame space 212 formed inside the first frame 210.

The first plate 111 may be partitioned into a plurality of parts. In the illustrated exemplary embodiment, the first plate 111 includes a first portion 111a which is located on a relatively upper side to cover the first space 212a of the first frame space 212 and a second portion 111b which is located on a relatively lower side to cover the second space 212b of the first frame space 212.

In this case, the first portion 111a and the second portion 111b may be formed to correspond to the shapes of the first space 212a and the second space 212b. In the illustrated exemplary embodiment, the first portion 111a has a hexagonal shape as a whole, and the upper edge thereof is formed to have a cross-section which extends longer than the hexagonal edge. In addition, the second portion 111b is formed to have a rectangular cross-section in which the extension length in the left-right direction is longer than the extension length in the up-down direction.

The shapes of the first portion 111a and the second portion 111b may be changed according to the shapes of the first space 212a and the second space 212b.

A plurality of through-holes are formed inside the first plate 111. In the illustrated exemplary embodiment, the first coupling opening 112 and the cover communication hole 113 are formed inside the first plate 111.

The first coupling opening 112 is a space through which the purification module 300 penetrates. Specifically, the body portion 310 of the purification module 300 is penetrated and coupled to the first coupling opening 112.

The first coupling opening 112 is formed to penetrate through the thickness direction of the first plate 111 and communicates the first frame space 212 with the outside. The purification module 300 which is coupled to penetrate through the first coupling opening 112 may extend into the first frame space 212.

The first coupling opening 112 may be sealed by the purification module 300. In other words, the first coupling opening 112 through which the purification module 300 penetrates may be closed to block communication between the outside and the first frame space 212. That is, the purification module 300 is hermetically coupled to the first coupling opening 112. To this end, a member such as an O-ring may be provided in the purification module 300.

Therefore, the external fluid may flow into the first frame space 212 only through a hollow formed inside the body portion 310 of the purification module 300.

The first coupling opening 112 may have any shape into which the purification module 300 may be coupled to penetrate. In the illustrated exemplary embodiment, the purification module 300, that is, the outer periphery of the body portion 310 is formed to have a circular cross-section, and the first coupling opening 112 is also formed to have a circular cross-section.

A plurality of first coupling openings 112 may be formed. The plurality of first coupling openings 112 are spaced apart from each other such that the plurality of purification modules 300 may be coupled to penetrate, respectively.

In the illustrated exemplary embodiment, the first coupling openings 112 are disposed adjacent to each other radially inside each corner of the first plate 111. In this case, an imaginary line extending along the plurality of first coupling openings 112 disposed on the outermost side has a hexagonal shape.

In other words, the plurality of first coupling openings 112 are arranged in a total of five columns, and three first coupling openings 112 are provided in the uppermost and lowermost rows, respectively, four first coupling openings 112 are formed in the second upper most and second lowermost rows, and five first coupling openings 112 are formed in the central row, respectively.

In the above exemplary embodiment, the plurality of first coupling openings 112 and the plurality of purification modules 300 penetrating through the same may be evenly distributed along the left-right direction or up-and-down direction. Accordingly, the path of the fluid passing through the purification module 300 and flowing into the housing 10 may also be formed uniformly with respect to the cross-section of the first plate 111.

The number and arrangement of the plurality of first coupling openings 112 may be changed.

The cover communication hole 113 communicates the outside with the first frame space 212, and specifically, the second space 212b. The cover communication hole 113 is formed to penetrate through the thickness direction of the first plate 111 to communicate the outside with the second space 212b. Dust passed through the purification module 300 and separated from the fluid may be discharged to the outside by a suction device (not illustrated) inserted into the cover communication hole 113.

The cover communication hole 113 may have any shape into which the suction device (not illustrated) may be inserted. In the illustrated exemplary embodiment, the cover communication hole 113 is formed to have a circular cross-section.

The cover communication hole 113 may be formed at any position which is capable of communicating the outside with the second space 212b. In the illustrated exemplary embodiment, the cover communication hole 113 is formed on the lower side of the first coupling opening 112, that is, on the second portion 111b of the first plate 111.

The cover communication hole 113 may be open or closed. When the cover communication hole 113 is closed, communication between the first frame space 212 and the outside may be blocked. When the cover communication hole 113 is opened, the suction device is drawn into the first frame space 212 such that collected dust may be discharged. To this end, a cover cap 114 is provided in the cover communication hole 113.

The cover cap 114 is detachably coupled to the cover communication hole 113 to open or close the cover communication hole 113. Communication between the first frame space 212 and the outside may be allowed or blocked by the cover cap 114.

The cover cap 114 may have any shape which is capable of opening or closing the cover communication hole 113. In the illustrated exemplary embodiment, the cover cap 114 is similar to the cover communication hole 113 and has a cylindrical shape with a circular cross-section and a length in the front-back direction.

The cover cap 114 may be formed of a material having predetermined elasticity. As the cover cap 114 is elastically deformed to a certain extent, the closed state of the cover communication hole 113 may be stably maintained. In an exemplary embodiment, the cover cap 114 may be formed of a rubber material.

The second cover 120 is disposed to face the first cover 110 with the first frame 210 interposed therebetween.

The second cover 120 forms a part of the inside of the fluid purification apparatus 40. In the illustrated exemplary embodiment, the second cover 120 is positioned between the first frame 210 and the second frame 220 to form a middle part of the fluid purification apparatus 40.

The second cover 120 is disposed to face the first cover 110 with the first frame 210 interposed therebetween. In addition, the second cover 120 is disposed to face the coupling frame 230 with the second frame 220 interposed therebetween.

The second cover 120 is coupled to the first frame 210. Specifically, the second cover 120 covers the first frame space 212 formed inside the first frame 210 from the inner side, which is the back side in the illustrated exemplary embodiment, and is coupled to the first frame 210. In an exemplary embodiment, the second cover 120 may be closely coupled to the first frame 210.

The second cover 120 is coupled to the second frame 220. Specifically, the second cover 120 covers the second frame space 222 formed inside the second frame 220 from the outer side, which is the back side in the illustrated exemplary embodiment, and is coupled to the second frame 220. In an exemplary embodiment, the second cover 120 may be closely coupled to the second frame 220.

The second cover 120 is coupled to the purification module 300. The second cover 120 is configured to support the other part of the purification module 300, which is the back side in the illustrated exemplary embodiment. This is achieved by penetrating and coupling the purification module 300 to the second coupling opening 122 formed in the second cover 120. In the illustrated exemplary embodiment, the second vortex forming member 330 is coupled to the second cover 120.

The second cover 120 is respectively coupled to the first frame 210 and the second frame 220 to seal the first frame space 212 and the second frame space 222, and it may be any shape that can partially support the purification module 300. In the illustrated exemplary embodiment, the second cover 120 has a polygonal plate shape including a plurality of corners.

Specifically, in the illustrated exemplary embodiment, the second cover 120 includes a first portion which is located on the upper side and extends in a horizontal direction, and a pair of second portions which extend downward from each end of the first portion and includes one bent portion protruding outward. Additionally, in the illustrated exemplary embodiment, the first cover 110 includes a third portion which extends vertically downward from each end of the second portion and a fourth portion which extends between each end of the third portion.

The second cover 120 is disposed to overlap the first cover 110 and the frame portion 200 along the thickness direction thereof, which is in the front-back direction in the illustrated exemplary embodiment.

In the illustrated exemplary embodiment, the second cover 120 includes a second plate 121 and a second coupling opening 122.

The second plate 121 forms the body of the second cover 120. The second plate 121 is provided in a plate shape and coupled to the first frame 210 and the second frame 220, respectively. The second plate 121 is disposed to cover the first frame space 212 formed inside the first frame 210 and the second frame space 222 formed inside the second frame 220.

The second plate 121 may be partitioned into a plurality of parts. In the illustrated exemplary embodiment, the second plate 121 is located on a relatively upper side and includes a first portion 121a which is located on a relatively upper side and covers the first space 212a and the second frame space 222 of the first frame space 212 and a second portion 121b which is located on relatively lower side and covers the second space 212b of the first frame space 212.

In this case, the first portion 121a and the second portion 121b may be formed to correspond to the shapes of the first space 212a, the second space 212b and the second frame space 222 of the first frame space 212. In the illustrated exemplary embodiment, the first portion 121a is formed to have a hexagonal cross-section as a whole. In addition, the second portion 121b is formed to have a rectangular cross-section in which the extension length in the left-right direction is longer than the extension length in the up-down direction.

The shapes of the first portion 121a and the second portion 121b may be changed according to the shapes of the first space 212a, the second space 212b and the second frame space 222.

A plurality of through-holes are formed inside the second plate 121. In the illustrated exemplary embodiment, the second coupling opening 122 is formed inside the second plate 121.

The second coupling opening 122 is a space through which the purification module 300 penetrates. Specifically, the second vortex forming member 330 of the purification module 300 is coupled to penetrate through the second coupling opening 122.

The second coupling opening 122 is formed to penetrate through the thickness direction of the second plate 121 to communicate the first frame space 212 and the second frame space 222. The purification module 300 which is coupled to penetrate through the second coupling opening 122 may extend into the first frame space 212 or the second frame space 222.

The second coupling opening 122 may be sealed by the purification module 300. In other words, the second coupling opening 122 through which the purification module 300 passes may be closed to block communication between the first frame space 212 and the second frame space 222. That is, the purification module 300 is hermetically coupled to the second coupling opening 122. To this end, a packing member (not illustrated) may be additionally provided in the purification module 300.

Accordingly, the fluid introduced into the body portion 310 of the purification module 300 may flow into the second frame space 222 only through the second vortex forming member 330.

The second coupling opening 122 may have any shape through which the purification module 300 may be formed to penetrate. In the illustrated exemplary embodiment, the purification module 300, that is, the outer periphery of the second vortex forming member 330 is formed to have a circular cross-section, and the second coupling opening 122 is also formed to have a circular cross-section.

A plurality of second coupling openings 122 may be formed. The plurality of second coupling openings 122 are spaced apart from each other such that the plurality of purification modules 300 may be coupled to penetrate, respectively.

In the illustrated exemplary embodiment, the second coupling openings 122 are disposed adjacent to each other radially inside each corner of the second plate 121. In this case, an imaginary line extending along the plurality of second coupling openings 122 disposed on the outermost side has a hexagonal shape.

In other words, the plurality of second coupling openings 122 are arranged in a total of five columns, and three second coupling openings 122 are provided in the uppermost and lowermost rows, four second coupling openings 122 are formed in the second uppermost and second lowermost rows, and five second coupling openings 122 are formed in the central row, respectively.

In the above exemplary embodiment, the plurality of second coupling openings 122 and the plurality of purification modules 300 penetrating through the same may be evenly distributed along the left-right direction or up-down direction. Accordingly, the path of a fluid passing through the purification module 300 and flowing into the housing 10 may also be formed uniformly with respect to the cross-section of the second plate 121.

It will be understood that the number and arrangement of the plurality of second coupling openings 122 correspond to the number and arrangement of the plurality of first coupling openings 112. The plurality of second coupling openings 122 and the plurality of first coupling openings 112 may be disposed to overlap each other in the thickness direction of the cover portion 100, which is in the front-back direction in the illustrated exemplary embodiment.

The number and arrangement of the plurality of second coupling openings 122 may be changed according to the number and arrangement of the plurality of first coupling openings 112.

The cover portion 100 is coupled to the frame portion 200.

The frame portion 200 forms another part of the exterior of the fluid purification apparatus 40. A space communicating with the through-hole of the cover portion 100 is formed inside the frame portion 200. The purification module 300 may be accommodated in the space, or the fluid passing through the purification module 300 may flow therein. That is, the frame portion 200 forms a space in which the purification module 300 is accommodated and a space in which a fluid flows.

The frame portion 200 is coupled to the cover portion 100. The frame portion 200 is coupled to the cover portion 100 while forming a space therebetween. The purification module 300 may be accommodated in the space, or the fluid passing through the purification module 300 may flow therein.

The frame portion 200 may be tightly coupled to the cover portion 100. That is, a space formed between the frame portion 200 and the cover portion 100 is sealed by the frame portion 200 and the cover portion 100 such that any communication with the outside may be blocked. Therefore, as described above, the external fluid may be introduced into the space between the frame portion 200 and the cover portion 100 only when it passes through the purification module 300.

The frame portion 200 is disposed to overlap the filter member 20, the blowing fan 30 and the cover portion 100 in the thickness direction thereof, which is in the front-back direction in the illustrated exemplary embodiment. In addition, the frame portion 200 partially accommodates the purification module 300 therein.

A plurality of frame portions 200 may be provided. The plurality of frame portions 200 may be respectively positioned between the plurality of cover portions 100. In the illustrated exemplary embodiment, the frame portion 200 includes a first frame 210, a second frame 220 and a coupling frame 230.

The first frame 210 is positioned between the first cover 110 and the second cover 120, and is coupled to the first cover 110 and the second cover 120, respectively. The second frame 220 is positioned between the second cover 120 and the coupling frame 230, and is coupled to the second cover 120 and the coupling frame 230, respectively. The coupling frame 230 is positioned between the second frame 220 and the filter frame 12, and is coupled to the second frame 220 and the filter frame 12, respectively.

Therefore, it can be said that the cover portion 100 and the frame portion 200 are alternately arranged with each other along the stacking direction thereof.

The first frame 210 forms a part of the fluid purification apparatus 40. In addition, the first frame 210 forms a part of the frame portion 200. In the illustrated exemplary embodiment, the first frame 210 is positioned between the first cover 110 and the second cover 120, forming the front side of the frame portion 200. In other words, the first frame 210 is disposed to be most spaced apart from the housing 10 among the components of the frame portion 200.

The first frame 210 is coupled to the first cover 110. Specifically, the first frame 210 is coupled such that the space formed therein (i.e., the first frame space 212) is covered by the first cover 110. In an exemplary embodiment, the first frame 210 may be closely coupled to the first cover 110.

The first frame 210 is coupled to the second cover 120. Specifically, the first frame 210 is coupled such that the first frame space 212 formed therein is covered by the second cover 120. In an exemplary embodiment, the first frame 210 and the second cover 120 may also be closely coupled.

That is, the first frame 210 is disposed between the first cover 110 and the second cover 120. The first frame 210 is disposed to overlap the first cover 110 and the second cover 120.

The first frame 210 partially accommodates the purification module 300. Specifically, the first frame 210 accommodates a part of the body portion 310 and a part of the second vortex forming member 330 in the first frame space 212 formed therein.

The first frame 210 is coupled to the first cover 110 and the second cover 120 to accommodate the purification module 300, and the internal space thereof may be of any shape that can block any communication with the outside. In the illustrated exemplary embodiment, the first frame 210, like the first cover 110, has a polygonal cross-section including a plurality of corners and is formed to have a thickness in the front-back direction.

Due to the shape of the first frame 210, dust which has been separated from the fluid passing through the purification module 300 may be collected on one side of the inside of the first frame 210. The detailed description thereof will be described below.

In the illustrated exemplary embodiment, the first frame 210 includes a first frame outer periphery 211, a first frame space 212, a frame communication hole 213 and a frame cap 214.

The first frame outer periphery 211 forms an exterior of the first frame 210. The first frame outer periphery 211 is formed to surround the first frame space 212 from the outside. That is, the first frame outer periphery 211 may be defined as an outer surface of the first frame 210.

The first frame outer periphery 211 may be divided into a plurality of parts. Each of the plurality of parts may be continuous with each other such that the first frame outer periphery 211 may be formed as a closed loop. In the illustrated exemplary embodiment, the first frame outer periphery 211 includes a first portion which is disposed on the upper side and formed in a hexagonal cross-sectional shape, and a second portion which is disposed on the lower side and formed in a quadrangular cross-sectional shape.

The first portion is disposed to surround the first space 212a of the first frame space 212. The second portion is disposed to surround the second space 212b of the first frame space 212.

As described above, the same number of purification modules 300 may be disposed along the extension direction of the first frame outer periphery 211 due to the shape of the first portion. Accordingly, it has been seen that the external fluid may be evenly introduced into the plurality of purification modules 300.

In this case, the parts forming the lateral direction among the corners of the first portion, which are the left part and the right part in the illustrated exemplary embodiment, preferably extend obliquely downward. Due to the shape, dust or the like introduced into the first space 212a may fall and be collected in the second space 212b without staying in the first portion.

A frame communication hole 213 may be formed in the first frame outer periphery 211. The frame communication hole 213 is opened and closed by the frame cap 214 such that communication between the first frame space 212 and the outside may be allowed or blocked.

A space surrounded by the first frame outer periphery 211 is defined as a first frame space 212.

The first frame space 212 is a space formed inside the first frame 210. The purification module 300 is partially accommodated in the first frame space 212. In addition, dust which has been separated from the purification module 300 may be accommodated in the first frame space 212.

The first frame space 212 is defined as being surrounded by the first frame outer periphery 211. In the illustrated exemplary embodiment, the first frame space 212 is formed as a space which is radially formed inside the first frame outer periphery 211 and has a polygonal cross-section.

The first frame space 212 may be closed in the thickness direction thereof by the first cover 110 and the second cover 120. That is, in the illustrated exemplary embodiment, the front side of the first frame space 212 is closed by the first cover 110. In addition, the back side of the first frame space 212 is closed by the second cover 120.

The first frame space 212 communicates with the purification module 300. Specifically, the first frame space 212 communicates with a body hollow 313 by a dust discharge portion 316 formed in the purification module 300. Dust separated from the fluid flowing in the purification module 300 may flow into the first frame space 212 through the dust discharge portion 316.

The first frame space 212 may be communicated with or blocked from the outside. Specifically, the first frame space 212 may communicate with the outside through the frame communication hole 213. When the frame cap 214 is inserted into and coupled to the frame communication hole 213, communication between the first frame space 212 and the outside may be blocked.

The first frame space 212 may be divided into a plurality of spaces. In the illustrated exemplary embodiment, the first frame space 212 includes a first space 212a which is located on the upper side and is formed to have a hexagonal cross-section and a second space 212b which communicates with the first space 212a and is located on the lower side and has a square cross-section.

The purification module 300 is partially accommodated in the first space 212a. Specifically, a part of the body portion 310 is accommodated in the first space 212a. The first space 212a is communicated with the body hollow 313 by the dust discharge portion 316 such that the separated dust and the like may flow into the first space 212a. The first space 212a communicates with the second space 212b.

The first space 212a may communicate with the outside through the frame communication hole 213. A member for cleaning the first space 212a, such as a blower, may enter the first space 212a through the frame communication hole 213.

The second space 212b accommodates dust or the like that flows into the first space 212a and falls. The second space 212b communicates with the first space 212a and is positioned below the first space 212a. Therefore, even when no external force is applied, dust or the like introduced into the first space 212a may fall due to its own weight and be collected in the second space 212b.

The second space 212b may communicate with the outside through the cover communication hole 113. A member for removing dust collected in the second space 212b, for example, a suction member, may enter the second space 212b through the cover communication hole 113.

The frame communication hole 213 communicates the first frame space 212 and the outside. The frame communication hole 213 is formed through the first frame outer periphery 211.

The frame communication hole 213 may be formed at any position which is capable of communicating the first frame space 212 and the outside. In the illustrated exemplary embodiment, the frame communication hole 213 is formed in an upper part of the first portion of the first frame outer periphery 211, that is, a part extending obliquely downward and outward.

In the above exemplary embodiment, a blower or the like passing through the frame communication hole 213 may spray a fluid for cleaning from the upper part to the lower part of the first space 212a.

The frame communication hole 213 may have any shape which is capable of communicating the first frame space 212 and the outside. In the illustrated exemplary embodiment, the frame communication hole 213 is formed to have a circular cross-section.

A plurality of frame communication holes 213 may be formed. The plurality of frame communication holes 213 may be formed at different positions to communicate with the first frame space 212 and the outside, respectively. In the illustrated exemplary embodiment, the frame communication hole 213 includes a first communication hole 213a which is formed on the left side and a second communication hole 213b which is formed on the right side.

The frame cap 214 may be inserted into and coupled to the frame communication hole 213 to be retractable.

The frame cap 214 is coupled to the frame communication hole 213 to seal the frame communication hole 213. Accordingly, communication between the first frame space 212 and the outside may be blocked.

The frame cap 214 may be inserted into and coupled to the frame communication hole 213 in a retractable manner. In other words, the frame cap 214 is detachably coupled to the frame communication hole 213.

The frame cap 214 may be formed of a material which is capable of a predetermined shape deformation. This is to store the restoring force through the shape deformation of the frame cap 214 and insert the same into the frame communication hole 213 such that the coupled state is stably maintained. In an exemplary embodiment, the frame cap 214 may be formed of a rubber material.

The frame cap 214 may be provided in any shape which is capable of being inserted into and coupled to the frame communication hole 213. In the illustrated exemplary embodiment, the frame cap 214 has a circular cross-section according to the shape of the frame communication hole 213 and extends in one direction.

A plurality of frame caps 214 may be provided. The plurality of frame caps 214 may be detachably coupled to the plurality of frame communication holes 213, respectively. In the illustrated exemplary embodiment, the frame cap 214 includes a first cap 214a which is inserted into the first communication hole 213a and a second cap 214b which is inserted into the second communication hole 213b.

The second frame 220 forms another part of the fluid purification apparatus 40. In addition, the second frame 220 forms another part of the frame portion 200. In the illustrated exemplary embodiment, the second frame 220 is located between the second cover 120 and the coupling frame 230, thereby forming a central part of the frame portion 200.

The second frame 220 is coupled to the second cover 120. Specifically, the second frame 220 is coupled to the second cover 120 while covering the space formed therein (i.e., the second frame space 222). In an exemplary embodiment, the second frame 220 may be closely coupled to the second cover 120.

The second frame 220 is coupled to the coupling frame 230. Specifically, the second frame 220 is coupled to the coupling frame 230 such that the second frame space 222 formed therein and the filter accommodating portion 232 formed inside the coupling frame 230 communicate with each other. In an exemplary embodiment, the second frame 220 and the coupling frame 230 may also be tightly coupled.

That is, the second frame 220 is disposed between the second cover 120 and the coupling frame 230. The second frame 220 is disposed to overlap the second cover 120 and the coupling frame 230.

The second frame 220 partially accommodates the purification module 300. Specifically, the second frame 220 accommodates a part of the second vortex forming member 330 in the second frame space 222 formed therein.

The second frame 220 communicates with the purification module 300. A fluid which has passed through the purification module 300 and separated from dust may flow into the second frame space 222.

The second frame 220 is positioned adjacent to the filter member 20. Specifically, the second frame 220 communicates with the filter member 20 which is supported by the coupling frame 230.

The second frame 220 may be coupled to the second cover 120 and the coupling frame 230 to communicate with the purification module 300, and have any shape in which the introduced fluid can flow through the filter member 20. At the same time, the second frame 220 may have any shape in which an internal space thereof may block any communication with the outside. In the illustrated exemplary embodiment, similar to the first portion 121a of the second cover 120, the second frame 220 is formed to have a hexagonal cross-section and have a thickness in the front-back direction.

Due to the shape of the second frame 220, the fluid passing through the purification module 300 which is coupled to the first portion 121a of the second cover 120 may flow into the second frame space 222. The detailed description thereof will be described below.

In the illustrated exemplary embodiment, the second frame 220 includes a second frame outer periphery 221 and a second frame space 222.

The second frame outer periphery 221 forms an exterior of the second frame 220. The second frame outer periphery 221 is formed to surround the second frame space 222 from the outside. That is, the second frame outer periphery 221 may be defined as an outer surface of the second frame 220.

The second frame outer periphery 221 may be divided into a plurality of parts. Each of the plurality of parts may be continuous with each other such that the second frame outer periphery 221 may be formed as a closed loop. In the illustrated exemplary embodiment, the second frame outer periphery 221 is formed to have a hexagonal cross-section.

The shape of the second frame outer periphery 221 may correspond to the shape of the first portion 121a of the second cover 120 to which the purification module 300 is coupled. Accordingly, the fluid which has passed through the purification module 300 and separated from dust may flow evenly into the second frame space 222.

A space surrounded by the second frame outer periphery 221 is defined as a second frame space 222.

The second frame space 222 is a space formed inside the second frame 220. The purification module 300 is partially accommodated in the second frame space 222. In addition, the fluid that has passed through the purification module 300 (i.e., the fluid from which dust and the like have been removed) may flow in the second frame space 222.

The second frame space 222 is defined as being surrounded by the second frame outer periphery 221. In the illustrated exemplary embodiment, the second frame space 222 is formed radially inside the second frame outer periphery 221 and has a polygonal cross-section.

One side of the second frame space 222 in the thickness direction may be closed by the second cover 120. In the illustrated exemplary embodiment, the front side of the second frame space 222 is closed by the second cover 120.

The other side of the second frame space 222 in the thickness direction may be covered by the coupling frame 230. In the illustrated exemplary embodiment, the back side of the second frame space 222 is partially closed by the coupling frame 230.

The remaining part of the other side of the second frame space 222 in the thickness direction may be covered by the filter member 20. In the illustrated exemplary embodiment, the inside of the back side of the second frame space 222 is covered by the filter member 20. The second frame space 222 communicates with the filter member 20.

Therefore, the fluid introduced into the second frame space 222 must pass through the filter member 20 to be introduced into the inner space of the housing 10 through the blowing fan 30.

The second frame space 222 communicates with the purification module 300. Specifically, the second frame space 222 communicates with a body hollow 313 of the purification module 300 by a vortex hollow 334 of the second vortex forming member 330. The fluid from which dust and the like have been removed may flow into the second frame space 222 through the vortex hollow 334.

The coupling frame 230 forms another part of the fluid purification apparatus 40. In addition, the coupling frame 230 forms the remaining part of the frame portion 200. In the illustrated exemplary embodiment, the coupling frame 230 is positioned between the second frame 220 and the filter frame 12 to form a rear side part of the frame portion 200.

The coupling frame 230 is coupled to the second frame 220. Specifically, the coupling frame 230 is coupled to the second frame 220 such that the filter accommodating portion 232 formed therein covers the second frame space 222. The filter accommodating portion 232 and the filter member 20 accommodated therein communicate with the second frame space 222. In an exemplary embodiment, the coupling frame 230 may be tightly coupled to the second frame 220.

The coupling frame 230 is coupled to the filter member 20. Specifically, the filter member 20 is accommodated in the filter accommodating portion 232 formed inside the coupling frame 230. A fluid which has been introduced into the second frame space 222 may pass through the filter member 20 and enter the housing 10.

The coupling frame 230 is coupled to a filter frame 12. Specifically, the coupling frame 230 and the filter frame 12 are coupled such that the filter accommodating portion 232 formed inside the coupling frame 230 overlaps a filter opening 13. In an exemplary embodiment, the coupling frame 230 may be detachably coupled to the filter frame 12.

That is, the combining frame 230 is disposed between the second frame 220 and the filter frame 12. The coupling frame 230 is disposed to overlap the second frame 220 and the filter frame 12.

The coupling frame 230 communicates with the second frame 220. A fluid which has been introduced into the second frame space 222 may flow to the filter member 20 supported by the coupling frame 230.

The coupling frame 230 communicates with the filter frame 12 and the blowing fan 30. A fluid passing through the filter member 20 may flow to the filter opening 13 formed inside the filter frame 12 and the blowing fan 30.

The coupling frame 230 may be coupled to the second frame 220 and the filter frame 12 and may have any shape which is capable of communicating with the blowing fan 30. In the illustrated exemplary embodiment, the coupling frame 230 has a shape that is similar to the second frame outer periphery 221, and the upper part is provided in a polygonal plate shape extending longer than the second frame outer periphery 221.

In the illustrated exemplary embodiment, the coupling frame 230 includes a coupling frame outer periphery 231 and a filter accommodating portion 232.

The coupling frame outer periphery 231 forms an exterior of the coupling frame 230. The coupling frame outer periphery 231 is formed to surround the filter accommodating portion 232 from the outside.

The coupling frame outer periphery 231 is coupled to the second frame 220 and may have any shape which is capable of supporting the filter member 20. In the illustrated exemplary embodiment, the coupling frame outer periphery 231 is a hexagon, but has a polygonal plate shape with upper corners extending longer.

The coupling frame outer periphery 231 may have any shape in which the filter member 20 is supported and coupled to the second frame 220.

A through-space is formed inside the coupling frame outer periphery 231. The space is defined as the filter accommodating portion 232.

The filter accommodating portion 232 is a space through which the filter member 20 penetrates. The filter accommodating portion 232 is formed through the inside of the coupling frame outer periphery 231.

As described above, the coupling frame outer periphery 231 is formed in a plate shape. Accordingly, the filter accommodating portion 232 is also formed to have a relatively small thickness compared to the thickness of the filter member 20. Accordingly, the filter member 20 may pass through the filter accommodating portion 232, and each part in the thickness direction may be exposed to the outside of the filter accommodating portion 232.

In the illustrated exemplary embodiment, the front side part of the filter member 20 is exposed to the second frame space 222. In addition, the back side part of the filter member 20 is exposed to the filter opening 13.

The filter accommodating portion 232 may be formed in a shape corresponding to the filter member 20. In the illustrated exemplary embodiment, since the filter member 20 is provided in a rectangular plate shape having a rectangular cross-section and a thickness in the front-back direction, the filter accommodating portion 232 is also formed as a space in a rectangular plate shape having a rectangular cross-section and a thickness in the front-back direction.

The filter accommodating portion 232 communicates with the second frame space 222. The fluid which has been introduced into the second frame space 222 may flow into the inner space of the housing 10 through the filter member 20 accommodated in the filter accommodating portion 232.

Although reference numerals are not assigned, the coupling frame 230 may further include a hinge member, an axis member and a coupling member. The hinge member may be rotatably coupled to the support protrusion 14 which is provided on the filter frame 12. The coupling may be formed by the shaft member penetrating the hinge member and the support protrusion 140. In addition, the coupling member may be detachably coupled to the coupling protrusion 15.

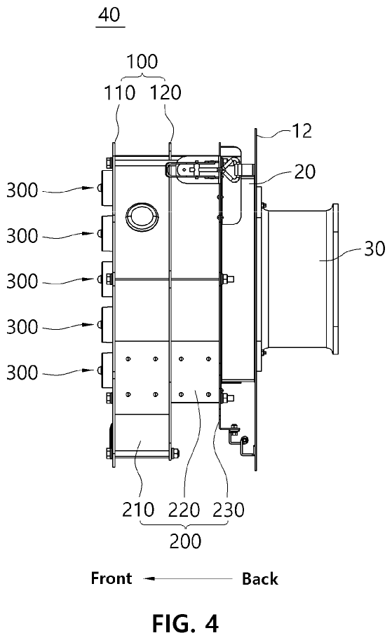

Referring back to FIGS. 3 and 4, the fluid purification apparatus 40 according to an exemplary embodiment of the present disclosure includes a purification module 300.

The purification module 300 primarily filters and removes dust mixed with the fluid before the external fluid passes through the filter member 20. The fluid may pass through the filter member 20 after relatively large particles among dust mixed with the fluid are preemptively removed by the purification module 300.

Accordingly, clogging of the filter member 20 by the large-sized particles may be prevented, and reliability of the filtering effect of the filter member 20 may be improved. Furthermore, the service lifespan or durability lifespan of the filter member 20 may also be increased.

The purification module 300 may be provided in any shape which is capable of separating and removing dust and the like mixed with the fluid. In the illustrated exemplary embodiment, the purification module 300 is configured to separate and remove dust and the like mixed with the fluid in the form of centrifugal separation.

That is, when the fluid flows in the form of a vortex, relatively large particles receive a greater centrifugal force than relatively small particles and move radially outward. The moved particles (i.e., relatively large particles) may be discharged to the outside of the purification module 300 and collected inside the frame portion 200.

The purification module 300 is coupled to the cover portion 100. Specifically, the purification module 300 is coupled to the first cover 110 and the second cover 120, respectively. As described above, the first cover 110 and the second cover 120 are disposed to face each other with the first frame 210 interposed therebetween and are spaced apart from each other.

Therefore, it can be said that the purification module 300 penetrates the first frame 210 and extends between the first cover 110 and the second cover 120. In the illustrated exemplary embodiment, the purification module 300 extends in the front-back direction.

One end of the purification module 300 in the extension direction, which is the front side end in the illustrated exemplary embodiment, is exposed to the outside (i.e., the front side) of the first cover 110 and communicates with the outside. An external fluid may flow into the purification module 300 through an opening formed at the end of the purification module 300.

The other end of the extension direction of the purification module 300, which is the back side end in the illustrated exemplary embodiment, is exposed to the inside (i.e., the back side) of the second cover 120 and communicates with the second frame space 222. After dust and the like are removed, an external fluid may flow into the second frame space 222 through an opening formed at the end of the purification module 300.

The purification module 300 extends inside the first frame space 212. The purification module 300 extends in the thickness direction of the first frame space 212, which is in the front-back direction in the illustrated exemplary embodiment.

The purification module 300 communicates with the first frame space 212. Dust or the like which has been separated from the fluid by the purification module 300 may be discharged to the first frame space 212. The detailed description thereof will be described below.

A plurality of purification modules 300 may be provided. The plurality of purification modules 300 may be coupled to the plurality of first coupling openings 112 formed in the first cover 110 and the plurality of second coupling openings 122 formed in the second cover 120, respectively. To this end, the plurality of first coupling openings 112 and the plurality of second coupling openings 122 may be disposed on the same line.

The number of purification modules 300 may be changed. That is, the number of purification modules 300 may vary according to the amount of heat generated by the operation of the power device 1. In this case, the number of first coupling openings 112 and second coupling openings 122 respectively formed on the first cover 110 and the second cover 120 may also be changed according to the number of purification modules 300.

Alternatively, the numbers of first coupling openings 112 and second coupling openings 122 may be greater than or equal to the number of purification modules 300 that are provided. In the above exemplary embodiment, the first coupling opening 112 or the second coupling opening 122 to which the purification module 300 is not coupled may be sealed by a sealing member (not illustrated).

In the illustrated exemplary embodiment, the purification module 300 includes a body portion 310, a first vortex forming member 320 and a second vortex forming member 330.

The body portion 310 forms a body of the purification module 300. A space communicating with the outside is formed inside the body portion 310. The external fluid may flow in the space and be separated from dust mixed therewith.

The body portion 310 extends in one direction. The one direction may be defined as the same direction as a direction in which the cover portion 100 and the frame portion 200 are stacked. In the illustrated exemplary embodiment, the body portion 310 extends in the front-back direction.

One side of the extension direction of the body portion 310 is coupled to the first cover 110. In the illustrated exemplary embodiment, the front side of the body portion 310 is through-coupled to the first coupling opening 112 of the first cover 110. The front side end of the body portion 310 is exposed to the outside of the first cover 110 such that the external fluid may flow into the body portion 310.

The other side of the extension direction of the body portion 310 is coupled to the second cover 120. In the illustrated exemplary embodiment, the back side of the body portion 310 is coupled to the second plate 121 of the second cover 120 by the second vortex forming member 330. Therefore, the back side end of the body portion 310 is closed by the second vortex forming member 330.

The remaining part of the body portion 310 is accommodated in the first frame space 212 of the first frame 210. The inner space of the body portion 310 communicates with the first frame space 212 by a dust discharge portion 316 to be described below.

The body portion 310 may be coupled to the first cover 110 and the second cover 120, respectively, and may have any shape in which a fluid may flow. In the illustrated exemplary embodiment, the body portion 310 has a ring-shaped cross-section with a hollow inside, and has a cylinder shape extending in the front-back direction. The shape of the body portion 310 may be changed according to the shapes of the first coupling opening 112 and the second coupling opening 122.

In the illustrated exemplary embodiment, the body portion 310 includes a body outer periphery 311, a body inner periphery 312, a body hollow 313, a first body end 3140, a second body end 315, a dust discharge portion 316 and a guide protrusion 317.

The body outer periphery 311 forms an outer periphery of the body portion 310. The body outer periphery 311 may be defined as an outer surface of the body portion 310. As described above, the body portion 310 has a cylindrical shape with a hollow inside, and the body outer periphery 311 may be referred to as a side surface of the body portion 310.

The body outer periphery 311 is a part where the body portion 310 is coupled to the first cover 110. When the body portion 310 passes through the first coupling opening 112, the body outer periphery 311 may be hermetically coupled to the inner peripheral surface surrounding the first coupling opening 112. To this end, the outer diameter of the body outer periphery 311 and the inner diameter of the first coupling opening 112 may be the same.

The body inner periphery 312 forms an inner periphery of the body portion 310. The body inner periphery 312 may be defined as an inner surface of the body portion 310.

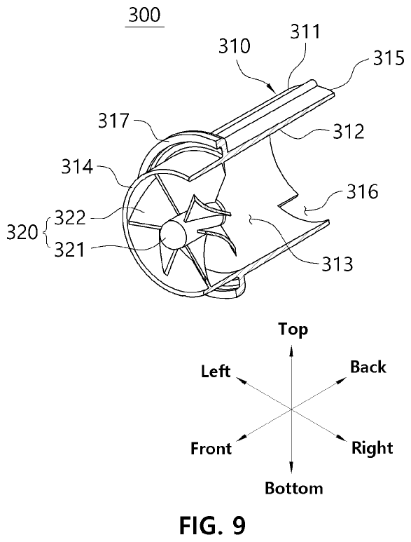

The body inner periphery 312 is a part where the body portion 310 is coupled to the first vortex forming member 320. As illustrated in FIG. 9, an end part of the first vortex forming member 320 in the radial direction may be coupled to the body inner periphery 312. That is, it may be said that the body inner periphery 312 supports the first vortex forming member 320.

The body hollow 313 is a space formed inside the body portion 310. The body hollow 313 may be defined as a space surrounded by the body inner periphery 312.

The body hollow 313 extends along a direction in which the body portion 310 extends. In the illustrated exemplary embodiment, the body hollow 313 extends in the front-back direction. Each end of the extension direction of the body hollow 313, which is the front side end and the back side end in the illustrated exemplary embodiment, is respectively formed to be open. That is, the body hollow 313 is formed to penetrate through the inside of the body portion 310 along the extension direction.

The body hollow 313 communicates with the outside through the front side end. An external fluid may be introduced into the body hollow 313 through the front side end of the body hollow 313.

The back side end of the body hollow 313 is sealed by the second vortex forming member 330. The fluid introduced into the body hollow 313 passes through the first vortex forming member 320 and flows in the form of a vortex, then collides with the second vortex forming member 330 and flows in the opposite direction, and afterwards, it may flow to the second frame space 222 through the second vortex forming member 330.

The body hollow 313 communicates with the first frame space 212. Specifically, the body hollow 313 communicates with the body hollow 313 by the dust discharge portion 316 such that dust or the like which has been separated from the fluid may be discharged into the first frame space 212.

The first vortex forming member 320 is accommodated in the body hollow 313. In the exemplary embodiment illustrated in FIG. 9, the first vortex forming member 320 is disposed on the outer side of the body hollow 313, that is, adjacent to the front side end.

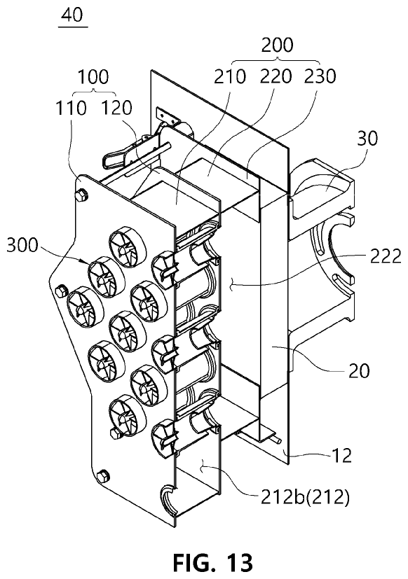

The second vortex forming member 330 is accommodated in the body hollow 313. Referring to FIGS. 13 to 15, the second vortex forming member 330 is disposed at the back side end of the body hollow 313 to be spaced apart from the body inner periphery 312. To this end, the diameter of the body hollow 313, that is, the diameter of the body inner periphery 312 may be formed to be greater than or equal to the outer diameter of the second vortex forming member 330.

The body hollow 313 may have any shape which is capable of accommodating the first vortex forming member 320 and forming a passage through which the fluid flows while dust mixed with the fluid is separated. In the illustrated exemplary embodiment, the body hollow 313 has a circular cross-section and is formed as a cylindrical space extending in the front-back direction.

A first body end 314 forms one end of the extension direction of the body portion 310. In the illustrated exemplary embodiment, the first body end 314 forms the front side end of the body portion 310 extending in the front-back direction.

The first body end 314 is exposed to the outer side of the first cover 110. In the illustrated exemplary embodiment, the first body end 314 is exposed to the front side of the first cover 110.

The first body end 314 is configured to surround the one side of the body hollow 313, which is the front side end in the illustrated exemplary embodiment. An external fluid may be introduced into the body portion 310 through the end of the body hollow 313 surrounded by the first body end portion 314.

The second body end 315 forms the other end of the extension direction of the body portion 310. In the illustrated exemplary embodiment, the second body end 315 forms the back side end of the body portion 310 extending in the front-back direction.

The second body end 315 is accommodated in the first frame space 212. In addition, the second body end 315 is coupled to the second vortex forming member 330.

The dust discharge portion 316 communicates the body hollow 313 and the first frame space 212. Dust or the like which has been separated from the fluid may be discharged to the first frame space 212 through the dust discharge portion 316.

The dust discharge portion 316 is formed through one part of the body outer periphery 311 and the body inner periphery 312. Referring to FIG. 9, the dust discharge portion 316 is formed at the back lower part of the body outer periphery 311 and the body inner periphery 312.

Accordingly, dust which has been centrifuged from the fluid flowing in the vortex form in the body hollow 313 may be discharged to the first frame space 212 through the dust discharge portion 316 formed on the lower side of the back side.

The dust discharge portion 316 may have any shape which is capable of communicating the body hollow 313 and the first frame space 212. In the illustrated exemplary embodiment, the cross-section of the dust discharge portion 316 is formed in an arc shape extending along the body outer periphery 311 and the body inner periphery 312.

The detailed description of a process in which the separated dust is discharged to the first frame space 212 through the dust discharge portion 316 will be described below.

A guide protrusion 317 limits the distance at which the body portion 310 is inserted into the cover 100 and the frame 200. In other words, the guide protrusion 317 is configured to limit the distance that the body portion 310 is moved to the back side. Accordingly, the body portion 310 may be inserted only until the second body end portion 315 comes into close contact with the second vortex forming member 330.

The guide protrusion 317 is formed on the body outer periphery 311 of the body. The guide protrusion 317 protrudes radially outward from the body outer periphery 311 and extends along the circumferential direction. Accordingly, the outer diameter of the guide protrusion 317 is formed to be greater than the outer diameter of the body outer periphery 311 and the inner diameter of the first coupling opening 112.

Accordingly, as the insertion of the body portion 310 proceeds, the guide protrusion 317 comes into contact with the first plate 111, and thus, the coupling length of the purification module 300 may be limited.

The first vortex forming member 320 causes the fluid introduced into the body hollow 313 to flow in a vortex form. By the first vortex forming member 320, the introduced fluid flows while forming a vortex such that mixed dust and the like may be centrifuged.

The first vortex forming member 320 is accommodated inside the body portion 310. Specifically, the first vortex forming member 320 is accommodated in the body hollow 313.

The first vortex forming member 320 may be positioned to be biased to one end of the body hollow 313. In the illustrated exemplary embodiment, the first vortex forming member 320 is positioned to be biased to the front side end of the body hollow 313. Accordingly, the first vortex forming member 320 may be disposed to be exposed to the outside. That is, the first vortex forming member 320 is disposed on the upstream side of the flow of the fluid formed inside the body portion 310.

Since the end is an inlet through which an external fluid flows into the body hollow 313, the external fluid flowing in may pass through the first vortex forming member 320 and flow in the form of a vortex.

The first vortex forming member 320 is coupled to the body portion 310. Specifically, each end of the first vortex forming member 320 in the radial direction, that is, each end of the blade 322 to be described below, is coupled to the body inner periphery 312.

The first vortex forming member 320 may be provided in any shape which is capable of forming the flow of the passing fluid in the form of a vortex. In the illustrated exemplary embodiment, the first vortex forming member 320 is provided in the form of a vane.

In the illustrated exemplary embodiment, the first vortex forming member 320 includes a vortex axis 321 and a blade 322.

The vortex axis 321 forms the center of the first vortex forming member 320. The vortex axis 321 is coupled to the plurality of blades 322 to partially form a path of fluid passing through the first vortex forming member 320.

The vortex axis 321 may extend in the extension direction of the body portion 310, which is in the front-back direction in the illustrated exemplary embodiment. The vortex axis 321 may extend on the central axis of the body portion 310. Accordingly, it will be understood that the vortex axis 321 is disposed on the central axis of the first coupling opening 112 and the second coupling opening 122.

The blade 322 is coupled in the radial direction of the vortex axis 321.

The blade 322 substantially serves to form a flow of fluid passing through the first vortex forming member 320 into a vortex. The blade 322 is coupled to the vortex axis 321 and the body inner periphery 312, respectively. That is, the blade 322 extends between the vortex axis 321 and the body inner periphery 312.

The outer surface of the blade 322 may be formed to have a curved shape. The curved surface may be formed to have different curvatures along the extension direction of the body portion 310, which is in the front-back direction in the illustrated exemplary embodiment. Accordingly, the introduced fluid may flow in a vortex form.

A plurality of blades 322 may be provided. The plurality of blades 322 may be disposed to be spaced apart from each other along the outer peripheral direction of the vortex axis 321. The plurality of blades 322 may form a flow of fluid passing therebetween in a vortex form.

The detailed description of the flow of a fluid passing through the first vortex forming member 320 and the process of separating dust and the like will be described below.

The second vortex forming member 330 re-forms the flow of the fluid formed by the first vortex forming member 320 (i.e., the vortex flow) and discharges the fluid into the second frame space 222. By the second vortex forming member 330, the flow of the fluid in the form of a vortex is strengthened such that mixed dust and the like may be centrifuged more effectively.

The second vortex forming member 330 is accommodated inside the body portion 310. Specifically, the second vortex forming member 330 is accommodated in the body hollow 313.

The second vortex forming member 330 may be positioned to be biased to the other end of the body hollow 313. In the illustrated exemplary embodiment, the second vortex forming member 330 is positioned to be biased to the back side end of the body hollow 313. Accordingly, the second vortex forming member 330 is not exposed to the outside. That is, the second vortex forming member 330 is disposed on the downstream side of the flow of the fluid formed inside the body portion 310.

The end may be defined as a downstream end of the fluid flowing in the body hollow 313. Therefore, the fluid flowing in the body hollow 313 collides with the second vortex forming member 330 at the other end and flows toward the upstream side again, and then, it may flow into the second frame space 222 through a vortex hollow 334 formed inside the second vortex forming member 330.

The second vortex forming member 330 is coupled to the second cover 120. Specifically, the second vortex forming member 330 is inserted into and coupled to the second coupling opening 122 of the second cover 120 at one end in the extension direction, which is the back side end in the illustrated exemplary embodiment.

In this case, the second vortex forming member 330 may be tightly coupled to the second coupling opening 122. Accordingly, the fluid flowing in the body hollow 313 may flow into the second frame space 222 only through the vortex hollow 334.

The second vortex forming member 330 may be disposed to have the same central axis as the central axis of the body portion 310. In addition, the second vortex forming member 330 is disposed to be spaced apart from the body inner periphery 312. That is, the maximum value among the outer diameters of each component of the second vortex forming member 330 is smaller than the inner diameter of the body inner periphery 312.

Therefore, a space in which a fluid may flow in a vortex form is formed between the outer peripheral surface of the second vortex forming member 330 and the body inner peripheral 312.

The second vortex forming member 330 may be provided in any shape which is capable of forming the flow of a fluid flowing in a space that is spaced apart from the body inner periphery 312 in a vortex form. In the illustrated exemplary embodiment, the second vortex forming member 330 has a shape of a circular truncated cone whose diameter decreases in a direction toward the first vortex forming member 320, that is, toward the front side.

In the illustrated exemplary embodiment, the second vortex forming member 330 includes a base 331, a neck 332, a boss portion 333 and a vortex hollow 334.

The base 331 forms a part of the second vortex forming member 330. The base 331 is a part where the second vortex forming member 330 is coupled to the second cover 120.

In addition, the base 331 is a part where the body portion 310 is coupled to the second vortex forming member 330. The base 331 supports the second body end 315 of the body portion 310, which is the back side end in the illustrated exemplary embodiment.

The base 331 is respectively coupled to the second cover 120 and the body portion 310, and may have any shape which is capable of supporting the same. In the illustrated exemplary embodiment, the base 331 has a circular cross-section and is formed in a disk shape having a thickness in the extension direction of the body portion 310, that is, in the front-back direction.

The base 331 continues with neck 332. The neck 332 extends from one side of the base 331, which is the front side in the illustrated exemplary embodiment, in a direction opposite to the base 331, that is, the front side.

The body portion 310 is seated on the base 331. In this case, the body inner periphery 312 is disposed to be spaced apart from the neck outer periphery 332a of the neck 332. That is, the body portion 310 is seated on the base 331 such that the body inner periphery 312 surrounds the neck outer periphery 332a radially from the outside.

In the illustrated exemplary embodiment, the base 331 includes a first base surface 331a and a second base surface 331b.

The first base surface 331a forms one surface of the base 331. In the illustrated exemplary embodiment, the first base surface 331a forms the front side surface of the base 331.

The first base surface 331a may be formed in a shape corresponding to the base 331. In the illustrated exemplary embodiment, the first base surface 331a has the shape of a truncated cone in which the radial inner part is formed to protrude toward a front side than an outer part.

The body portion 310 is seated on the first base surface 331a. The second body end 315 may be tightly coupled to the first base surface 331a.

The neck 332 continues on the first base surface 331a. Specifically, the neck 332 extends radially inside the second body end 315 which is coupled to the first base surface 331a, in a direction opposite to the first base surface 331a, which is the front side in the illustrated exemplary embodiment.

The second base surface 331b is disposed to be opposite to the first base surface 331a.

The second base surface 331b forms the other surface of the base 331. In the illustrated exemplary embodiment, the second base surface 331b forms the back side surface of the base 331.

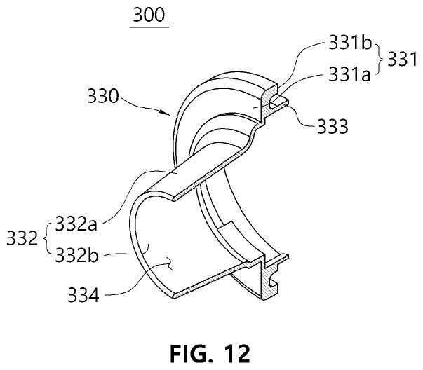

The second base surface 331b may extend along the outer periphery of the base 331 and may have a predetermined thickness in a radial direction. As illustrated in FIG. 12, the second base surface 331b is formed to protrude from the first base surface 331a toward the back side, and the length of the protrusion may be shorter than that of the boss portion 333.

The second base surface 331b is coupled to the second cover 120. Specifically, when the second vortex forming member 330 is coupled to the second cover 120, the second base surface 331b surrounds the second coupling opening 122 radially from the outside to be coupled to the front side end of the second plate 121.

Accordingly, the second base surface 331b may be defined as a part of the second vortex forming member 330 which is supported by the second cover 120.

The boss portion 333 is formed on the radially inner side of the second base surface 331b. The second base surface 331b is spaced apart from the boss portion 333 along the radial direction and is formed to surround the boss portion 333.

The neck 332 is a part that secondarily forms the flow of the fluid introduced into the body hollow 313 in the form of a vortex. The neck 332 is spaced apart from the body inner periphery 312 such that the fluid may flow in a vortex form in a space formed therebetween. That is, the neck 332 is accommodated in a hollow formed inside the flow of the vortex form formed by the fluid.

The neck 332 is continuous with base 331. The neck 332 is formed to extend from the first base surface 331a toward the first body end 314, which is toward the front side in the illustrated exemplary embodiment.

The neck 332 is accommodated in the body hollow 313. That is, one end of the neck 332 in the extension direction, which is the back side end in the illustrated exemplary embodiment, is coupled to the base 331. In addition, the other end of the neck 332 in the extension direction, which is the front side end in the illustrated exemplary embodiment, is accommodated in the body hollow 313. In this case, the front side end is spaced apart from the body inner periphery 312 and is maintained in a floating state.

The neck 332 may have any shape which is capable of forming the flow of a fluid in a vortex form together with the body portion 310. In the illustrated exemplary embodiment, the neck 332 has a circular cross-section, but is in the shape of a truncated cone with the diameter of the cross-section decreasing towards a direction opposite to the base 331, that is, towards the front side.

Inside the neck 332, a vortex hollow 334 extending to and penetrating the inside of the base 331 is formed such that the fluid which has been separated from dust and the like may flow into the second frame space 222.

The neck 332 is positioned adjacent to a dust discharge portion 316. In the illustrated exemplary embodiment, the neck 332 is located above the dust discharge portion 316, and dust or the like which has been separated from the fluid may be discharged into the first frame space 212 through the dust discharge portion 316.

In the illustrated exemplary embodiment, the neck 332 includes a neck outer periphery 332a and a neck inner periphery 332b.

The neck periphery 332a forms the outer periphery of the neck 332. The neck outer periphery 332a may be defined as an outer surface of the neck 332. As described above, the neck 332 has a truncated conical shape through which the vortex hollow 334 penetrates therein, and the neck outer periphery 332a may be referred to as a side surface of the neck 332.

The neck outer periphery 332a is spaced apart from the body inner periphery 312 to form a space. A fluid introduced from the outside may flow in the space. As described above, the fluid passes through the first vortex forming member 320 and flows in a vortex form.

The fluid formed at this time passes through the space formed between the neck outer periphery 332a and the body inner periphery 312, collides with the second cover 120, and then proceeds toward the first vortex forming member 320 again.

The neck inner periphery 332b forms the inner periphery of the neck 332. The neck inner periphery 332b may be defined as an inner surface of the neck 332. The neck inner periphery 332b is formed to be opposite to the neck outer periphery 332a. The neck inner periphery 332b partially surrounds the vortex hollow 334.

The neck inner periphery 332b may be formed such that the diameter of the cross-section changes along the extension direction of the neck 332. In the illustrated exemplary embodiment, the diameter of the cross-section of the neck inner periphery 332b is formed to increase in a direction from the front side toward the back side, that is, in a direction toward the base 331.

The neck inner periphery 332b partially surrounds the vortex hollow 334 formed therein. In this case, as described above, it will be understood that the diameter of the cross-section of the neck inner periphery 332b changes along the extension direction of the neck 332, and the diameter of the cross-section of the vortex hollow 334 also changes along the extension direction.

The neck inner periphery 332b surrounds the fluid flowing in the vortex hollow 334 in a radial direction. The fluid flowing in the vortex hollow 334 flows in a vortex form by the neck inner periphery 332b, but does not arbitrarily flow out in the radial direction.

The boss portion 333 is a part where the second vortex forming member 330 is coupled to the second cover 120. The boss portion 333 is inserted into and coupled to the second coupling opening 122 formed in the second cover 120.

In an exemplary embodiment, the boss portion 333 may be inserted and coupled while sealing the second coupling opening 122. In the above exemplary embodiment, the fluid introduced into the purification module 300 may flow into the second frame space 222 only through the vortex hollow 334 and the second coupling opening 122.

The boss portion 333 is continuous with the base 331. In the exemplary embodiment illustrated in FIG. 12, the boss portion 333 is formed to protrude from the radially inner side of the second base surface 332b in a direction opposite to the neck 332, that is, toward the back side.

The boss portion 333 may extend in an outer peripheral direction of the base 331. In this case, the boss portion 333 extends on the radially inner side of the second base surface 331b in the circumferential direction. Accordingly, the boss portion 333 is formed to have an annular cross-section with a smaller diameter than the diameter of the second base surface 331b.

The boss portion 333 extends by a predetermined length toward the back side in a direction toward the second cover 120, which is the back side in the illustrated exemplary embodiment. The extension length of the boss portion 333 may be formed to be longer than that of the second base surface 331b.

Therefore, the second vortex forming member 330 and the second cover 120, the boss portion 333 is inserted into and coupled to the second coupling opening 122, and the second base surface 331b may be disposed to be in contact with the front side surface of the second plate 121.

Inside the boss portion 333, a vortex hollow 334 is partially formed.

The vortex hollow 334 functions as a passage through which the fluid secondarily flowing in a vortex form by the second vortex forming member 330 flows out into the second frame space 222. The vortex hollow 334 is formed to extend in the extension direction the second vortex forming member 330, which is in the front-back direction in the illustrated exemplary embodiment.

Each end in the extension direction of the vortex hollow 334, which is the front side end and the back side end in the illustrated exemplary embodiment, is respectively formed to be open. The front side end of the vortex hollow 334 communicates with the body hollow 313. The back side end of the vortex hollow 334 communicates with the second coupling opening 122.

That is, the vortex hollow 334 is formed to penetrate through the inside of the second vortex forming member 330. The fluid introduced through the front side end of the vortex hollow 334 may flow into the second frame space 222 through the back side end of the vortex hollow 334.

The vortex hollow 334 may be partially formed inside various components constituting the second vortex forming member 330. In the illustrated exemplary embodiment, the vortex hollow 334 is formed to penetrate through the inside of the base 331, the neck 332 and the boss portion 333.

The vortex hollow 334 may be formed such that the cross-sectional area is changed along the extension direction. That is, as illustrated in FIG. 12, the vortex hollow 334 is formed such that the cross-sectional area thereof increases along a direction toward the second cover 120.

The vortex hollow 334 may have any shape in which a fluid flows in a vortex form and flows out into the second frame space 222. In the illustrated exemplary embodiment, the vortex hollow 334 is circular, but is formed as a truncated cone-shaped space in which the cross-sectional area increases toward the back side.

### 4. Description of the Flow of a Fluid Formed Inside the Fluid Purification Apparatus 40 According to an Exemplary Embodiment of the Present Disclosure

The fluid purification apparatus 40 according to an exemplary embodiment of the present disclosure may form the flow of the introduced external fluid in a vortex form through the above-described configuration. The fluid introduced into the fluid purification apparatus 40 flows in a vortex form, and mixed dust and the like may be centrifuged to be removed.

The fluid introduced into the fluid purification apparatus 40 flows as described above, and after dust and the like are separated, the fluid may be introduced into the housing 10 through the filter member 20. That is, the fluid for cooling the components of the power device 1 is introduced into the housing 10 after passing through at least two filtration processes.

In addition, as the fluid flows in the form of a vortex, the fluid may pass through the filter member 20 after large-sized dust and the like are removed by centrifugation. Accordingly, a phenomenon in which the filter member 20 is clogged with large-sized dust or the like may be prevented, and the filtration efficiency and durability lifespan of the filter member 20 may be increased.

Hereinafter, with reference to FIGS. 13 to 15, the flow of a fluid formed inside the fluid purification apparatus 40 according to an exemplary embodiment of the present disclosure and the process of separating dust mixed with the fluid according to the flow will be described in detail.

The term “first flow (F1)” used in the following description refers to the flow proceeding in a direction toward the second cover 120, that is, toward the back side in the illustrated exemplary embodiment, in the flow of a fluid formed in the body hollow 313. The first flow (F1) is formed in the body hollow 313 and formed on the outer side of the second vortex forming member 330.

The term “second flow (F2)” used in the following description refers to the flow proceeding in a direction opposite to the second cover 120, that is, the front side in the illustrated exemplary embodiment, in the flow of a fluid formed in the body hollow 313. The second flow (F2) is also formed in the body hollow 313 and formed on the outer side of the second vortex forming member 330.

In this case, it will be understood that the first flow (F1) corresponds to a relatively upstream side of the fluid flow, and the second flow (F2) corresponds to a relatively downstream side of the fluid flow.

In addition, the term “dust flow (FD)” used in the following description refers to the flow of dust or the like which is mixed with a fluid and then separated from the fluid by being centrifuged by the flow of a fluid.

Referring to FIG. 13, the partially cut-away perspective view of a fluid purification apparatus 40 according to an exemplary embodiment of the present disclosure is illustrated. In the illustrated exemplary embodiment, the front side end of the purification module 300 communicates with the outside such that an external fluid may flow into the purification module 300. The back side end of the purification module 300 communicates with the second frame space 222 such that the fluid from which dust and the like have been separated may flow into the second frame space 222.

In this case, since the purification module 300 communicates only with the first frame space 212 and the second frame space 222, the fluid introduced into the purification module 300 does not flow out arbitrarily.

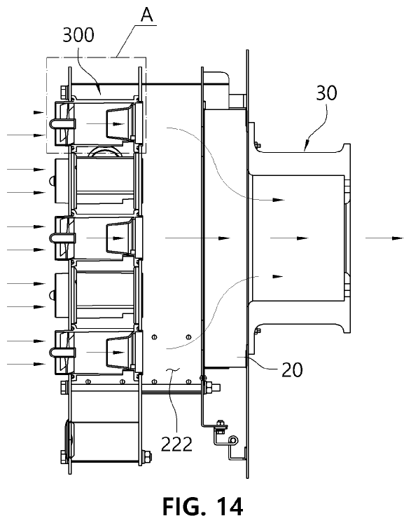

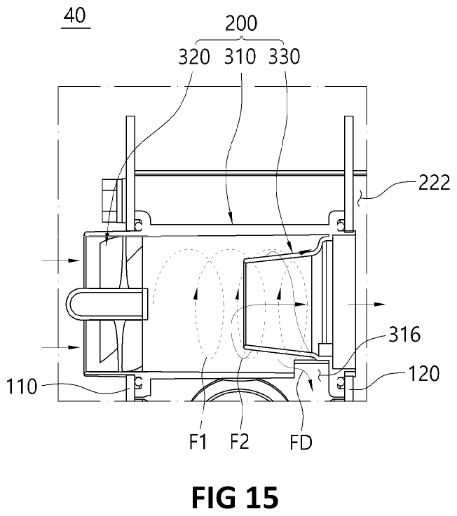

Referring to FIGS. 14 and 15, the flow process of a fluid formed inside the fluid purification apparatus 40 according to an exemplary embodiment of the present disclosure is illustrated.

First of all, the external fluid is introduced into the body hollow 313 through the front side end of the purification module 300. In this case, since a plurality of purification modules 300 are provided and disposed in different positions, the external fluid is respectively introduced into a plurality of body hollows 313 formed inside a plurality of purification modules 300.

In this case, the external fluid passes through the first vortex forming member 320 which is positioned adjacent to the front side end of the purification module 300 and then flows into the body hollow 313. Accordingly, the first flow (F1) is formed as a swirling vortex and flows in the body hollow 313. In this case, it will be understood that the traveling direction of the first flow (F1) is a direction from the first vortex forming member 320 toward the second vortex forming member 330.

As the first flow (F1) is formed as a vortex in a swirling form, centrifugal force is generated in the fluid in a radially outward direction, that is, in a direction toward the body inner periphery 312. Accordingly, particles having a relatively large mass, that is, relatively large dust and the like are moved radially outward.

The fluid reaching the second vortex forming member 330 collides with the second cover 120 and then flows toward the first vortex forming member 320 again. In this case, due to the shape of the second vortex forming member 330, the second flow (F2) is also formed as a vortex in a swirling form. Accordingly, centrifugal force is generated in the fluid in a direction toward the body inner periphery 312, and dust and the like are additionally moved radially outward.

The dust discharge portion 316 is formed to penetrate through the body outer periphery 311 and the body inner periphery 312 to communicate the body hollow 313 and the first frame space 212. In an exemplary embodiment, the dust discharge portion 316 may be formed on the lower side of the body portion 310. Accordingly, dust which has been separated from the fluid passes through the dust discharge portion 316 and is discharged to the first frame space 212.

That is, the dust flow (FD) extends from the radially outer side of the body hollow 313 to the first frame space 212 through the dust discharge portion 316.

Meanwhile, the second flow (F2) extends along the neck 332 of the second vortex forming member 330 in a direction toward the first vortex forming member 320, which is the front side in the illustrated exemplary embodiment. The second flow (F2) extending to the front side end of the neck 332 is introduced into the openly formed vortex hollow 334. The fluid introduced into the vortex hollow 334 flows into the second frame space 222 communicating with the vortex hollow 334.

Thereafter, the fluid passes through the filter member 20 and is filtered again, and then flows into the inner space of the housing 10 via the blowing fan 30 to cool the components of the power device 1. In the above process, it will be understood that the blowing fan 30 is operated to provide a transfer force to the external fluid.

The power device 1 according to an exemplary embodiment of the present disclosure described above may filter a fluid at least twice, by including centrifugal separation by the fluid purification apparatus 40 and filtration by the filter member 20.

Therefore, components accommodated inside the housing 10 are not damaged by dust mixed with the fluid for cooling. Furthermore, since the filter member 20 is configured to filter dust or the like having a relatively small size, it is possible to prevent clogging of the filter member 20.

Although the exemplary embodiments of the present disclosure have been described above, the spirit of the present disclosure is not limited to the exemplary embodiments presented in the present specification, and those skilled in the art who understand the spirit of the present disclosure may easily suggest other exemplary embodiments by changing, modifying, deleting or adding components within the scope of the same spirit, but this will also fall within the scope of the present disclosure.

| | |
|---|---|
| 1: Power device | 10: Housing |
| 11: Outer surface | 12: Filter frame |
| 13: Filter opening | 14: Support protrusion |
| 15: Coupling protrusion | 20: Filter member |
| 30: Blowing fan | 40: Fluid purification apparatus |
| 100: Cover portion | 110: First cover |
| 111: First plate | 111a: First portion |
| 111b: Second portion | 112: First coupling opening |
| 113: Cover communication hole | 114: Cover cap |
| 120: Second cover | 121: Second plate |
| 121a: First portion | 121b: Second portion |
| 122: Second coupling opening | 200: Frame portion |
| 210: First frame | |
| 211: First frame outer periphery | |
| 212: First frame space | 212a: First space |
| 212b: Second space | 213: Frame communication hole |
| 213a: First communication hole | 213b: Second communication hole |
| 214: Frame cap | 214a: First cap |
| 214b: Second cap | 220: Second frame |
| 221: Second frame outer periphery | 222: Second frame space |
| 230: Coupling frame | |
| 231: Coupling frame outer periphery | |
| 232: Filter accommodating portion | 300: Purification module |
| 310: Body portion | 311: Body outer periphery |
| 312: Body inner periphery | 313: Body hollow |
| 314: First body end | 315: Second body end |
| 316: Dust discharge portion | 317: Guide protrusion |
| 320: First vortex forming member | 321: Vortex axis |
| 322: Blade | |
| 330: Second vortex forming member | |
| 331: Base | 331a: First base surface |
| 331b: Second base surface | 332: Neck |
| 332a: Neck outer periphery | 332b: Neck inner periphery |
| 333: Boss portion | 334: Vortex hollow |
| F1: First flow | F2: Second flow |
| FD: Dust flow | |

1. A fluid purification apparatus, comprising:
a frame portion having a space formed therein;
a cover portion covering the space of the frame portion and coupled to the frame portion; and
purification modules each of which passes through the frame portion and the cover portion, and is in communication with the outside and the space in the frame portion,
wherein each purification module comprises:
a body portion forming a part of the exterior and having an inner portion that is in communication with the outside and the space in the frame portion to form a flow path through which a fluid from the outside flows; and
a vortex formation member accommodated in the body portion and provided to turn the fluid flow from the outside into the body portion into a vortex such that dust mixed in the fluid from the outside is centrifuged from the fluid while flowing in the vortex in the body portion.

2. The fluid purification apparatus of claim 1, wherein the cover portion comprises:
a first cover which is located on the outermost side and to which a part of the purification module is coupled; and
a second cover which is disposed to be spaced apart from the first cover along a direction in which the body portion of the purification module extends, and to which another part of the purification module is coupled.

3. The fluid purification apparatus of claim 2, wherein the first cover comprises:
a first plate which forms an exterior thereof; and
a first coupling opening which is formed to penetrate through the inside of the first plate in the thickness direction, and through which the purification module is coupled to penetrate.

4. The fluid purification apparatus of claim 2, wherein the second cover comprises:
a second plate which forms an exterior thereof; and
a second coupling opening which is formed to penetrate through the inside of the second plate in the thickness direction, and through which the purification module is coupled to penetrate.

5. The fluid purification apparatus of claim 2, wherein the frame portion comprises:
a first frame which is located between the first cover and the second cover, the inside of which is sealed by the first cover and the second cover;
a second frame which is disposed to face the first frame with the second cover therebetween, and has a space formed therein through which the fluid passing through the purification module flows; and
a coupling frame which is disposed to face the second cover with the second frame therebetween, and has a space formed therein for accommodating a filter member through which the fluid passes.

6. The fluid purification apparatus of claim 5, wherein the first frame comprises:
a first frame outer periphery which forms an exterior; and
a first frame space which is formed to be surrounded by the first frame outer periphery, is sealed by the first cover and the second cover, and is in communication with the inside of the body portion of the purification module, into which the centrifuged dust flows.

7. The fluid purification apparatus of claim 5, wherein the second frame comprises:
a second frame outer periphery which forms an exterior; and
a second frame space which is formed to be surrounded by the second frame outer periphery, and is sealed by the second cover, the coupling frame and a filter member that is accommodated in the coupling frame, and through which the fluid from which the dust has been separated flows.

8. The fluid purification apparatus of claim 1, wherein a body hollow which is formed to penetrate in the extension direction of the body portion is formed inside the body portion, and
wherein one end of the body hollow in the extension direction is formed to be open such that the external fluid flows in, and the other end thereof in the extension direction is formed to be open such that the fluid from which the dust has been removed flows out.

9. The fluid purification apparatus of claim 1, wherein the frame portion comprises:
a first frame having a first frame space formed therein into which the centrifuged dust flows; and
a second frame having a second frame space formed therein into which the fluid from which the dust has been separated flows.

10. The fluid purification apparatus of claim 9, wherein the body portion comprises a dust discharge portion which is formed to penetrate through the outer periphery and communicates with the inside of the body portion and the first frame space, and
wherein the dust separated from the inside of the body portion passes through the dust discharge portion and is discharged into the first frame space.

11. The fluid purification apparatus of claim 1, wherein the body portion is formed to extend in one direction such that one end in the extension direction of the body portion is exposed to the outside, and the other end in the extension direction of the body portion is accommodated inside the frame portion, and
wherein the vortex forming member is provided in plurality, and the plurality of vortex forming members are spaced apart from each other along the one direction and are disposed inside the body portion.

12. The fluid purification apparatus of claim 11, wherein the vortex forming member comprises:
a first vortex forming member which is located adjacent to the one end in the extension direction of the body portion and forms the flow of the fluid flowing into the body portion into a vortex shape.

13. The fluid purification apparatus of claim 12, wherein the first vortex forming member comprises:
a vortex axis which is located at the central axis of the body portion; and
a plurality of blades which extend in a curved shape between the vortex axis and the inner periphery of the body portion.

14. The fluid purification apparatus of claim 11, wherein the vortex forming member comprises:
a second vortex forming member which is located adjacent to the other end in the extension direction of the body portion and forms the flow of the fluid flowing into the body portion into a vortex shape.

15. The fluid purification apparatus of claim 14, wherein the second vortex forming member is formed to have a reduced cross-sectional area along a direction toward the one end in the extension direction of the body portion, and
wherein the interior of the second vortex forming member comprises a vortex hollow which is formed to penetrate through and communicates with the interior of the body portion and the interior of the frame portion, and through which the fluid from which the dust has been removed flows.

16. A power device, comprising:
a housing which has a space formed inside that communicates with the outside;
a filter member which is coupled to one surface of the housing to filter an external fluid flowing into the space of the housing; and
a fluid purification apparatus which covers the filter member and is coupled to the housing, and centrifugally separates dust mixed in the external fluid flowing into the space of the housing,
wherein the fluid purification apparatus and the filter member are arranged to overlap along a direction in which the external fluid flows into the space of the housing such that the external fluid sequentially passes through the fluid purification apparatus and the filter member to flow into the space of the housing.

17. The power device of claim 16, wherein the fluid purification apparatus comprises:
a frame portion which is physically partitioned and has a plurality of spaces formed therein through which the dust and the fluid from which the dust has been removed flow respectively;
a cover portion which seals each of the plurality of spaces of the frame portion and is coupled to the frame portion; and
a purification module which is configured to communicate with the outside, allow the fluid to flow in, and centrifugally separate the dust by forming the flow of the introduced fluid into a vortex shape, and respectively communicates with the plurality of spaces of the frame portion and discharges the separated dust and the fluid from which the dust has been separated into the plurality of spaces.

18. The power device of claim 17, wherein the purification module comprises:
a first vortex forming member which is located at one end of the extension direction and forms the flow of the introduced fluid into a vortex shape; and
a second vortex forming member which is located at the other end of the extension direction and forms the flow of the introduced fluid into a vortex shape.
